(19) United States
(12) Patent Application Publication
(10) Pub. No.: US 2022/0299871 A1
(43) Pub. Date: Sep. 22, 2022

(54) COLORING COMPOSITION, FILM, COLOR FILTER, SOLID-STATE IMAGING ELEMENT, AND IMAGE DISPLAY DEVICE

(71) Applicant: FUJIFILM Corporation, Tokyo (JP)

(72) Inventors: Takuya TSURUTA, Haibara-gun (JP); Takuro SUGIYAMA, Haibara-gun (JP); Yasuharu SHIRAISHI, Haibara-gun (JP); Akio MIZUNO, Haibara-gun (JP)

(73) Assignee: FUJIFILM Corporation, Tokyo (JP)

(21) Appl. No.: 17/835,665

(22) Filed: Jun. 8, 2022

Related U.S. Application Data
(63) Continuation of application No. PCT/JP2020/044964, filed on Dec. 3, 2020.

(30) Foreign Application Priority Data
Dec. 11, 2019 (JP) 2019-223426

(51) Int. Cl. G03F 7/00; G03F 7/027; C08K 5/56; C09B 47/10; G02B 5/22

(52) U.S. Cl. CPC G03F 7/0007; G03F 7/027; C08K 5/56; C09B 47/10; G02B 5/223; H01L 27/14621

(57) ABSTRACT

Provided are a coloring composition including a colorant, a polymerizable compound, and a photopolymerization initiator, in which the colorant includes a green pigment, a content of the green pigment in a total solid content of the coloring composition is 25% by mass or more, and the green pigment includes a compound which is a compound represented by Formula (1) and has a maximal absorption wavelength in a wavelength range of 620 to 730 nm; a film formed of the coloring composition; a color filter; a solid-state imaging element; and an image display device.

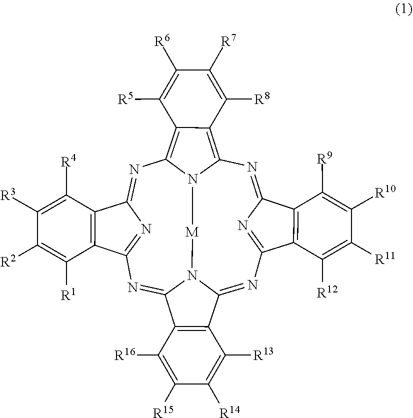

### CROSS-REFERENCE TO RELATED APPLICATIONS

This application is a Continuation of PCT International Application No. PCT/JP2020/044964 filed on Dec. 3, 2020, which claims priority under 35 U.S.C. § 119(a) to Japanese Patent Application No. 2019-223426 filed on Dec. 11, 2019. Each of the above application(s) is hereby expressly incorporated by reference, in its entirety, into the present application.

### BACKGROUND OF THE INVENTION

### 1. Field of the Invention

The present relates to a coloring composition including a green pigment. The present invention further relates to a film formed of the coloring composition, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element. The color filter normally includes pixels of three primary colors of red, green, and blue, and acts to separate transmitted light into the three primary colors.

Each color pixel of the color filter has been produced using a coloring composition including a colorant, a polymerizable compound, and a photopolymerization initiator. As the colorant, a phthalocyanine compound and the like have been known (see WO2019/167950A and JP2017-111398A).

### SUMMARY OF THE INVENTION

According to the study of the present inventor, it has been found that, in a case where a film is formed of a coloring composition including a relatively large amount of green pigments in the total solid content of the coloring composition, the green pigments tend to aggregate with each other in the film, and defects such as aggregates tend to occur.

Therefore, an object of the present invention is to provide a coloring composition that a film in which generation of defects is suppressed can be formed. Another object of the present invention is to provide a film formed of the coloring composition, a color filter, a solid-state imaging element, and an image display device.

According to the studies conducted by the present inventors, it has been found that the above-described object can be achieved by adopting the following configuration, thereby leading to the completion of the present invention. Therefore, the present invention provides the following.

<1> A coloring composition comprising:

a colorant;

a polymerizable compound; and

a photopolymerization initiator,

in which the colorant includes a green pigment,

a content of the green pigment in a total solid content of the coloring composition is 25% by mass or more, and

the green pigment includes a compound which is a compound represented by Formula (1) and has a maximal absorption wavelength in a wavelength range of 620 to 730 nm,

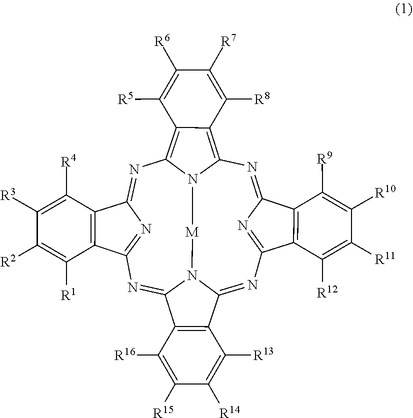

in the formula, R¹ to R¹⁶ each independently represent a hydrogen atom or a substituent,

at least one of R¹, . . . , or R¹⁶ is a group represented by Formula (R-1),

two adjacent groups of R¹ to R¹⁶ may be bonded to each other to form a ring, and

M represents a metal atom, a metal oxide, or a metal halide,

—X¹—R¹⁰⁰ (R-1)
in Formula (R-1), X¹ represents S or NR^{X1},
R^{X1} represents a hydrogen atom or a substituent,
R¹⁰⁰ represents a hydrogen atom or a substituent, and
in a case where X¹ is NR^{X1}, R¹⁰⁰ and R^{X1} may be bonded to each other to form a ring.

<2> A coloring composition according to <1>,

in which R¹⁰⁰ in Formula (R-1) is a group represented by Formula (R-2),

-A²-R²⁰⁰ (R-2)
in Formula (R-2), A² represents a single bond or a divalent linking group, and
R²⁰⁰ represents a hydrogen atom or a substituent,
where, in a case where R²⁰⁰ is an aryl group, A² is a single bond.

<3> The coloring composition according to <1> or <2>,

in which the content of the green pigment in the total solid content of the coloring composition is 45% by mass or more.

<4> The coloring composition according to any one of <1> to <3>,

in which at least one of R¹, . . . , or R⁴ in Formula (1), at least one of R⁵, . . . , or R⁸ in Formula (1), at least one of R⁹, . . . , or R¹² in Formula (1), and at least one of R¹³, . . . , or R¹⁶ in Formula (1) are each independently the group represented by Formula (R-1).

<5> The coloring composition according to any one of <1> to <4>,

in which X¹ in Formula (R-1) is S.

<6> The coloring composition according to any one of <1> to <5>,

in which M in Formula (1) is Cu, Zn, Fe, VO, or Mg.

<7> The coloring composition according to any one of <1> to <6>,

in which a molecular weight of the compound represented by Formula (1) is 2500 or less.

<8> The coloring composition according to any one of <1> to <7>, further comprising:

a yellow pigment.

<9> The coloring composition according to any one of <1> to <8>,

in which the coloring composition is used for forming a pixel of a color filter.

<10> The coloring composition according to <9>,

in which the coloring composition is used for forming a green pixel.

<11> A film obtained from the coloring composition according to any one of <1> to <10>.

<12> A color filter comprising:

the film according to <11>.

<13> A solid-state imaging element comprising:

the film according to <11>.

<14> An image display device comprising:

the film according to <11>.

According to the present invention, it is possible to provide a coloring composition that a film in which generation of defects is suppressed can be formed. According to the present invention, it is also possible is to provide a film formed of the coloring composition, a color filter, a solid-state imaging element, and an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a compound which is hardly dissolved in a solvent.

In the present specification, the term “step” is not only an independent step, but also includes a step which is not clearly distinguished from other steps in a case where an intended action of the step is obtained.

<Coloring Composition>

A coloring composition according to an embodiment of the present invention is a coloring composition including a colorant, a polymerizable compound, and a photopolymerization initiator, in which the colorant includes a green pigment, a content of the green pigment in a total solid content of the coloring composition is 25% by mass or more, and the green pigment includes a compound which is a compound represented by Formula (1) and has a maximal absorption wavelength in a wavelength range of 620 to 730 nm.

According to the coloring composition according to the embodiment of the present invention, a film in which generation of defects is suppressed can be formed even in a case where the content of the green pigment in the total solid content of the coloring composition is 25% by mass or more. The detailed reason for obtaining such an effect is not sure, but it is presumed to be due to the following reasons.

In general, the green pigment tends to have higher association than chromatic pigments of other hues. The reason for this is that, since the green pigment has absorption on a longer wavelength side than pigments of other hues, it is necessary to extend a conjugated system to lengthen the wavelength. This is because that, as the conjugated system is longer, interaction between substituents is higher and it is easier to associate. In particular, in a case of a compound including an aromatic ring as the conjugated system, such as a phthalocyanine compound, as the conjugated system is longer, interaction between the aromatic rings is higher and it tends to be easy to associate.

The coloring composition according to the embodiment of the present invention includes, as the green pigment, a compound which is a compound represented by Formula (1) described later and has a maximal absorption wavelength in a wavelength range of 620 to 730 nm. The compound represented by Formula (1) has a structure in which a group represented by Formula (R-1) described later is bonded to a phthalocyanine skeleton. Since the compound represented by represented Formula (1) has such a structure, by improving an electron density in the phthalocyanine skeleton, dispersibility in the film is improved. As a result, it is presumed that aggregation of the compounds represented by Formula (1) in the film, aggregation of the compound represented by Formula (1) and a green pigment other than the compound represented by Formula (1), and the like can be suppressed. Therefore, it is presumed that it is possible to form a film in which the generation of defects is suppressed.

The coloring composition according to the embodiment of the present invention can be preferably used as a coloring composition for forming a pixel of a color filter, and can be more preferably used as a coloring composition for forming a green pixel of a color filter. In addition, the coloring composition according to the embodiment of the present invention can also be used as a composition for forming a color microlens. Examples of a method for manufacturing the color microlens include the method described in JP2018-010162A.

Hereinafter, the respective components used in the coloring composition according to the embodiment of the present invention will be described.

<<Colorant>>

The coloring composition according to the embodiment of the present invention contains a colorant including a green pigment. As the colorant, a colorant including a green pigment is used. In the coloring composition according to the embodiment of the present invention, as the green pigment, a compound which is a compound (hereinafter, also referred to as a compound (1)) represented by Formula (1) and has a maximal absorption wavelength in a wavelength range of 620 to 730 nm is used. In the present specification, a pigment means a compound which is hardly dissolved in a solvent.

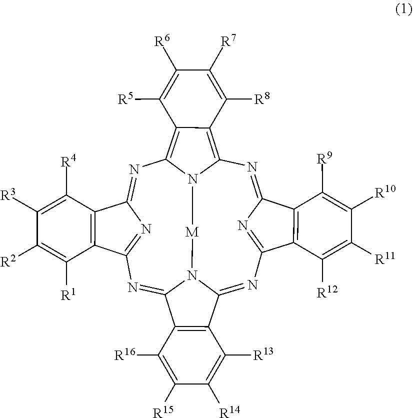

In the formula, R¹ to R¹⁶ each independently represent a hydrogen atom or a substituent,

at least one of R¹, . . . , or R¹⁶ is a group represented by Formula (R-1),

two adjacent groups of R¹ to R¹⁶ may be bonded to each other to form a ring, and

M represents a metal atom, a metal oxide, or a metal halide,

—X¹—R¹⁰⁰ (R-1)
in Formula (R-1), X¹ represents S or NR^{X1},
R^{X1} represents a hydrogen atom or a substituent,
R¹⁰⁰ represents a hydrogen atom or a substituent, and
in a case where X¹ is NR^{X1}, R¹⁰⁰ and R^{X1} may be bonded to each other to form a ring.

Examples of the substituent represented by R¹ to R¹⁶ in Formula (1) include the group represented by Formula (R-1), a halogen atom, an alkyl group, an aryl group, a heterocyclic group, a polymerizable group, —OR^{t1}, —COR^{t1}, —COOR^{t1}, —OCOR^{t1}, and a group represented by Formula (t-1). R^{t1} represents a hydrogen atom, an alkyl group, an aryl group, or a heterocyclic group, and R^{t2} to R^{t9} in Formula (t-1) each independently represent a hydrogen atom or an alkyl group.

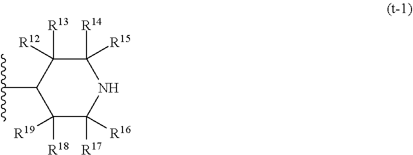

Examples of the halogen atom include a fluorine atom, a chlorine atom, a bromine atom, and an iodine atom.

The alkyl group preferably has 1 to 30 carbon atoms, more preferably has 1 to 15 carbon atoms, still more preferably has 1 to 8 carbon atoms, and particularly preferably has 1 to 5 carbon atoms. The alkyl group may be any of linear, branched, and cyclic forms, and is preferably linear or branched and more preferably linear. The alkyl group may have a substituent. Examples of the substituent include a substituent T described later and a polymerizable group.

The aryl group preferably has 6 to 30 carbon atoms, more preferably has 6 to 20 carbon atoms, and still more preferably has 6 to 12 carbon atoms. The aryl group may have a substituent. Examples of the substituent include a substituent T described later and a polymerizable group.

The heterocyclic group may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and still more preferably 3 to 12. The heterocyclic group may have a substituent. Examples of the substituent include a substituent T described later and a polymerizable group.

Examples of the polymerizable group include a vinyl group, an allyl group, a (meth)acryloyl group, and a (meth)acryloyloxy group.

M in Formula (1) represents a metal atom, a metal oxide, or a metal halide. Examples of the metal atom include Zn, Mg, Si, Sn, Rh, Pt, Pd, Mo, Mn, Pb, Cu, Ni, Co, and Fe. Examples of the metal oxide include TiO and VO. Examples of the metal halide include AlCl, InCl, FeCl, TiCl₂, SnCl₂, SiCl₂, and GeCl₂. From the reason that it is easier to form a film with fewer defects such as aggregates, M is preferably Cu, Zn, Fe, VO, or Mg, and more preferably Cu, VO, or Zn.

Next, a group represented by Formula (R-1) will be described.

X¹ in Formula (R-1) represents S or NR^{X1}, and R^{X1} represents a hydrogen atom or a substituent. Examples of the substituent represented by R^{X1} include an alkyl group, an aryl group, and a heterocyclic group. Preferred ranges of these groups are the same as those described above. From the reason that it contributes greatly to improvement of electron density, X¹ in Formula (R-1) is preferably S.

R¹⁰⁰ in Formula (R-1) represents a hydrogen atom or a substituent, and from the reason that solubility in a solvent is reduced and dispersibility is easily improved, it is preferable to be a substituent. Examples of the substituent represented by R¹⁰⁰ include the substituents described in the section of the substituent represented by R¹ to R¹⁶ described above, and from the reason that the solubility in a solvent is easily reduced, an alkyl group having 1 to 10 carbon atoms, an aryl group having 6 to 12 carbon atoms, a polymerizable group, or the above-described group represented by Formula (t-1) is preferable. The alkyl group and aryl group may have a substituent. Examples of the substituent which may be included in the alkyl group having 1 to 10 carbon atoms include a halogen atom, an aryl group, a polymerizable group, a hydroxy group, an alkoxy group, the group represented by Formula (t-1), a carboxy group, a sulfo group, a sulfonamide group, a sulfonimide group, an amino group, a cyano group, and a nitro group, and from the reason that the solubility in a solvent is easily reduced, a halogen atom, a polymerizable group, or a hydroxy group is preferable. Examples of the substituent which may be included in the aryl group having 6 to 12 carbon atoms include a halogen atom, an alkyl group, a polymerizable group, a hydroxy group, an alkoxy group, the group represented by Formula (t-1), a carboxy group, a sulfo group, a sulfonamide group, a sulfonimide group, an amino group, a cyano group, and a nitro group.

In addition, R¹⁰⁰ in Formula (R-1) is also preferably a group represented by Formula (R-2). According to this aspect, aggregation or the like of the pigments due to heating during film formation or heating after film formation can be effectively suppressed, and it is easy to form a film in which the generation of defects is suppressed.

-A²-R²⁰⁰ (R-2)

In Formula (R-2), A² represents a single bond or a divalent linking group, and R200 represents a hydrogen atom or a substituent. However, in a case where R200 is an aryl group, A² is a single bond.

Examples of the divalent linking group represented by A² include an alkylene group, an arylene group, an alkyleneoxy group, and a polyalkyleneoxy group. The alkylene group and alkyleneoxy group preferably have 1 to 30 carbon atoms, more preferably have 1 to 15 carbon atoms, and still more preferably have 1 to 8 carbon atoms. The arylene group preferably has 6 to 30 carbon atoms, more preferably has 6 to 20 carbon atoms, and still more preferably has 6 to 12 carbon atoms. The polyalkyleneoxy group is preferably a polyethyleneoxy group or a polypropyleneoxy group.

R²⁰⁰ is preferably a substituent. Examples of the substituent represented by R²⁰⁰ include the substituents described in the section of the substituent represented by R¹ to R¹⁶ described above, and an alkyl group having 1 to 10 carbon atoms, an aryl group having 6 to 12 carbon atoms, a polymerizable group, or the above-described group represented by Formula (t-1) is preferable. The alkyl group and aryl group may have a substituent. Examples of the substituent which may be included in the alkyl group include a halogen atom, a polymerizable group, a hydroxy group, an alkoxy group, and the group represented by Formula (t-1). Examples of the substituent which may be included in the aryl group include a halogen atom, an alkyl group, a polymerizable group, a hydroxy group, an alkoxy group, and the group represented by Formula (t-1).

(Substituent T)

Examples of a substituent T include a halogen atom, an alkyl group, an aryl group, a heterocyclic group, —OR^{t11}, —COR^{t11}, —COOR^{t11}, —OCOR^{t11}, —NR^{t11}R^{t12}, —NHCOR^{t11}, —CONR^{t11}R^{t12}, —NHCONR^{t11}R^{t12}, —NHCOOR^{t11}, —SR^{t11}, —SO₂R^{t11}, —SO₂OR^{t11}, —NHSO₂R^{t11}, —SO₂NR^{t11}R^{t12}, and the above-described group represented by Formula (t-1). R^{t11} and R^{t12} each independently represent a hydrogen atom, an alkyl group, an aryl group, or a heterocyclic group. R^{t11} and R^{t12} may be bonded to each other to form a ring.

Examples of the halogen atom include a fluorine atom, a chlorine atom, a bromine atom, and an iodine atom.

The alkyl group preferably has 1 to 30 carbon atoms, more preferably has 1 to 15 carbon atoms, still more preferably has 1 to 8 carbon atoms, and particularly preferably has 1 to 5 carbon atoms. The alkyl group may be any of linear, branched, and cyclic forms, and is preferably linear or branched and more preferably linear.

The aryl group preferably has 6 to 30 carbon atoms, more preferably has 6 to 20 carbon atoms, and still more preferably has 6 to 12 carbon atoms.

The heterocyclic group may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

In a case where these groups can further have a substituent, these groups may further have a substituent. Examples of the further substituent include the groups described above as the substituent T.

In Formula (1), at least one of R¹, . . . , or R¹⁶ is the group represented by Formula (R-1), it is preferable that at least two of R¹, . . . , or R¹⁶ are the groups represented by Formula (R-1), it is more preferable that at least three of R¹, . . . , or R¹⁶ are the groups represented by Formula (R-1), and it is still more preferable that at least four of R¹, . . . , or R¹⁶ are the groups represented by Formula (R-1). Among these, from the reason that the dispersibility is improved by reducing the solubility in a solvent, and the spectral characteristics are improved by being a single compound, it is preferable that at least one of R¹, . . . , or R⁴, at least one of R⁵, . . . , or R⁸, at least one of R⁹, . . . , or R¹², and at least one of R¹³, . . . , or R¹⁶ are each independently the group represented by Formula (R-1), and it is more preferable that at least two of R¹, . . . , or R⁴, at least two of R⁵, . . . , or R⁸, at least two of R⁹, . . . , or R¹², and at least two of R¹³, . . . , or R¹⁶ are each independently the group represented by Formula (R-1). In particular, it is preferable that R², R³, R⁶, R⁷, R¹⁰, R¹¹, R¹⁴, and R¹⁵ are each independently the group represented by Formula (R-1), and it is more preferable that R², R³, R⁶, R⁷, R¹⁰, R¹¹, R¹⁴, and R¹⁵ are each independently the group represented by Formula (R-1) and R¹, R⁴, R⁵, R⁸, R⁹, R¹², R¹³, and R¹⁶ are hydrogen atoms.

In Formula (1), two adjacent groups of R¹ to R¹⁶ may be bonded to each other to form a ring. For example, in a case where two adjacent groups of R¹ to R¹⁶ are each independently the group represented by Formula (R-1), R¹⁰⁰'s of the two adjacent groups may be bonded to each other to form a ring. The ring formed may be an aliphatic ring or an aromatic ring. In a case where two adjacent groups of R¹ to R¹⁶ are each independently the group represented by Formula (R-1) and R¹⁰⁰'s of the two adjacent groups may be bonded to each other to form a ring, by reducing molecular mobility of the compound, it can be expected that the pigment derivative is easier to approach and the dispersibility is improved. A compound having the following structure is a compound having a structure in which R², R³, R⁶, R⁷, R¹⁰, R¹¹, R¹⁴, and R¹⁵ are each independently the group represented by Formula (R-1), and R¹⁰⁰'s of R² and R³, R¹⁰⁰'s of R⁶ and R⁷, R¹⁰⁰'s of R¹⁰ and R¹¹, and R¹⁰⁰'s of R¹⁴ and R¹⁵ are each independently bonded to each other to form an aromatic ring.

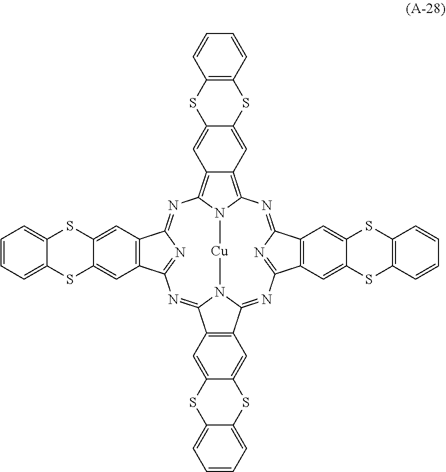

Specific examples of the compound (1) include compounds having a structure represented by Formula (1a) (Structural examples (A-1) to (A-25), (A-32) to (A-42), (A-44), and (A-45)), and compounds having a structure represented by Formulae (A-26) to (A-31), and (A-43). Structures of each element constituting M and R¹ to R¹⁶ in Formula (1a) are shown in the following table.

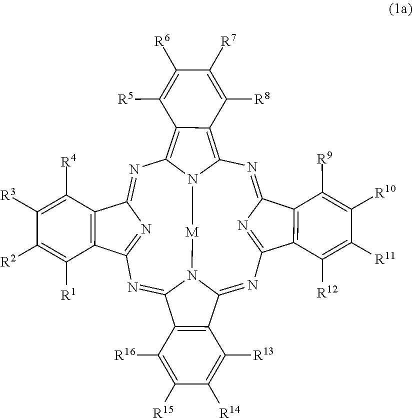

TABLE 1

| Structural | | | | | | | | | | | | | | | | | |
|---|---|---|---|---|---|---|---|---|---|---|---|---|---|---|---|---|---|
| example | M | R¹ | R² | R³ | R⁴ | R⁵ | R⁶ | R⁷ | R⁸ | R⁹ | R¹⁰ | R¹¹ | R¹² | R¹³ | R¹⁴ | R¹⁵ | R¹⁶ |
| A-1 | Cu | H | S-1 | S-1 | H | H | S-1 | S-1 | H | H | S-1 | S-1 | H | H | S-1 | S-1 | H |
| A-2 | Zn | H | S-1 | S-1 | H | H | S-1 | S-1 | H | H | S-1 | S-1 | H | H | S-1 | S-1 | H |
| A-3 | Fe | H | S-1 | S-1 | H | H | S-1 | S-1 | H | H | S-1 | S-1 | H | H | S-1 | S-1 | H |
| A-4 | Mg | H | S-1 | S-1 | H | H | S-1 | S-1 | H | H | S-1 | S-1 | H | H | S-1 | S-1 | H |
| A-5 | AlCl | H | S-1 | S-1 | H | H | S-1 | S-1 | H | H | S-1 | S-1 | H | H | S-1 | S-1 | H |
| A-6 | Cu | H | S-1 | S-1 | H | H | S-2 | S-2 | H | H | S-1 | S-1 | H | H | S-2 | S-2 | H |
| A-7 | Cu | H | S-1 | S-1 | H | H | N-1 | N-1 | H | H | N-1 | N-1 | H | H | S-1 | S-1 | H |
| A-8 | Cu | H | S-1 | H | H | H | S-1 | H | H | H | S-1 | H | H | H | S-1 | H | H |
| A-9 | Cu | H | S-1 | S-1 | H | H | Br | Br | H | H | S-1 | S-1 | H | H | Br | Br | H |
| A-10 | Cu | H | S-1 | S-1 | H | H | O-1 | O-1 | H | H | S-1 | S-1 | H | H | O-1 | O-1 | H |
| A-11 | Cu | H | S-1 | H | H | H | Cl | Cl | H | H | H | S-1 | H | H | Cl | Cl | H |
| A-12 | Cu | H | S-1 | H | H | H | Br | Br | H | H | Br | Br | H | H | Br | Br | H |
| A-13 | Cu | H | S-3 | S-3 | H | H | S-3 | S-3 | H | H | S-3 | S-3 | H | H | S-3 | S-3 | H |
| A-14 | Cu | H | S-4 | S-4 | H | H | S-4 | S-4 | H | H | S-4 | S-4 | H | H | S-4 | S-4 | H |
| A-15 | Cu | H | S-5 | S-5 | H | H | S-5 | S-5 | H | H | S-5 | S-5 | H | H | S-5 | S-5 | H |
| A-16 | Cu | H | S-6 | S-6 | H | H | S-6 | S-6 | H | H | S-6 | S-6 | H | H | S-6 | S-6 | H |
| A-17 | Zn | H | S-7 | S-7 | H | H | S-7 | S-7 | H | H | S-7 | S-7 | H | H | S-7 | S-7 | H |
| A-18 | Cu | H | S-2 | S-2 | H | H | S-2 | S-2 | H | H | S-2 | S-2 | H | H | S-2 | S-2 | H |
| A-19 | Cu | H | S-8 | S-8 | H | H | S-8 | S-8 | H | H | S-8 | S-8 | H | H | S-8 | S-8 | H |
| A-20 | Cu | H | N-2 | N-2 | H | H | N-2 | N-2 | H | H | O-1 | O-1 | H | H | N-2 | N-2 | H |
| A-21 | Cu | H | S-9 | S-9 | H | H | S-9 | S-9 | H | H | S-9 | S-9 | H | H | S-9 | S-9 | H |
| A-22 | Zn | H | S-10 | S-10 | H | H | S-10 | S-10 | H | H | S-10 | S-10 | H | H | S-10 | S-10 | H |
| A-23 | Cu | H | S-11 | S-11 | H | H | S-11 | S-11 | H | H | S-11 | S-11 | H | H | S-11 | S-11 | H |
| A-24 | Cu | H | S-12 | S-12 | H | H | S-12 | S-12 | H | H | S-12 | S-12 | H | H | S-12 | S-12 | H |
| A-25 | Cu | H | S-13 | S-13 | H | H | S-13 | S-13 | H | H | S-13 | S-13 | H | H | S-13 | S-13 | H |
| A-32 | Cu | H | S-14 | S-14 | H | H | S-14 | S-14 | H | H | S-14 | S-14 | H | H | S-14 | S-14 | H |
| A-33 | Zn | H | S-15 | S-15 | H | H | S-15 | S-15 | H | H | S-15 | S-15 | H | H | S-15 | S-15 | H |
| A-34 | Cu | H | S-16 | S-16 | H | H | S-16 | S-16 | H | H | S-16 | S-16 | H | H | S-16 | S-16 | H |
| A-35 | Cu | H | S-17 | S-17 | H | H | S-17 | S-17 | H | H | S-17 | S-17 | H | H | S-17 | S-17 | H |
| A-36 | Cu | H | N-3 | N-3 | H | H | N-3 | N-3 | H | H | N-3 | N-3 | H | H | N-3 | N-3 | H |
| A-37 | Cu | H | N-4 | N-3 | H | H | N-4 | N-4 | H | H | N-4 | N-4 | H | H | N-4 | N-4 | H |
| A-38 | Zn | H | N-5 | N-4 | H | H | N-5 | N-5 | H | H | N-5 | N-5 | H | H | N-5 | N-5 | H |
| A-39 | Cu | H | N-2 | N-2 | H | H | N-2 | N-2 | H | H | N-2 | N-2 | H | H | N-2 | N-2 | H |
| A-40 | Cu | H | S-14 | S-14 | H | H | S-14 | S-14 | H | H | S-14 | S-14 | H | H | S-14 | S-14 | H |
| A-41 | Cu | Cl | S-1 | S-1 | Cl | Cl | S-1 | S-1 | Cl | Cl | S-1 | S-1 | Cl | Cl | S-1 | S-1 | Cl |
| A-42 | Cu | S-1 | S-1 | S-1 | S-1 | S-1 | S-1 | S-1 | S-1 | S-1 | S-1 | S-1 | S-1 | S-1 | S-1 | S-1 | S-1 |
| A-44 | Cu | H | S-1 | H | H | Cl | Br | Br | Br | Cl | Br | Br | Br | Cl | Br | Br | Br |
| A-45 | VO | H | S-1 | H | H | H | S-1 | H | H | H | S-1 | H | H | H | S-1 | H | H |

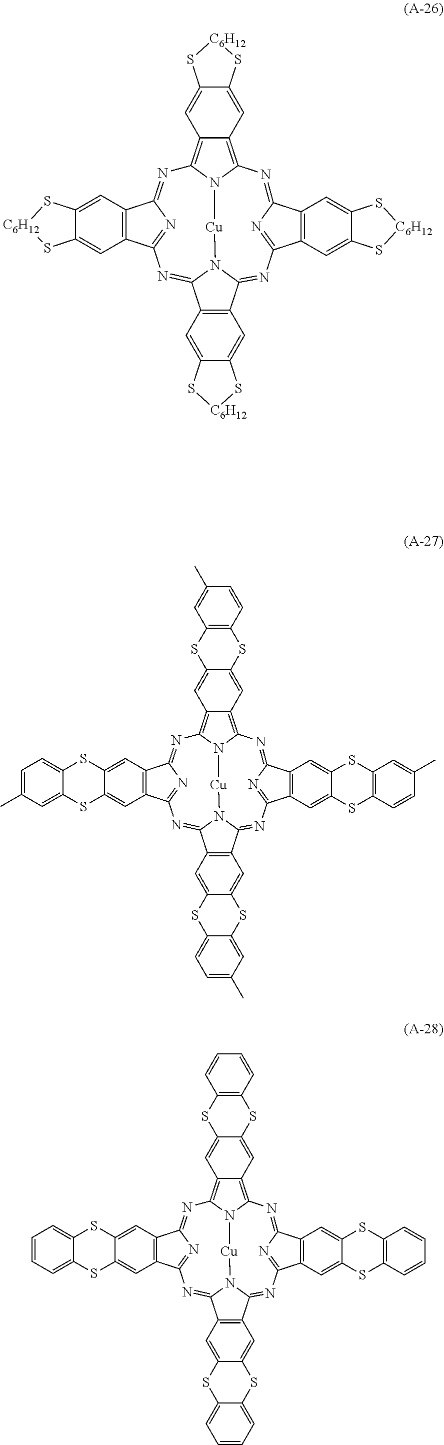

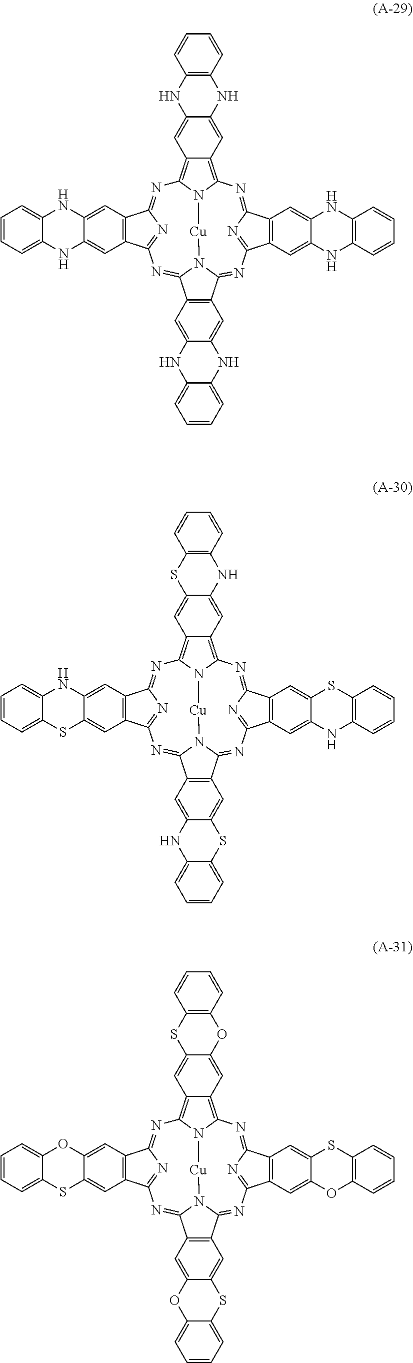

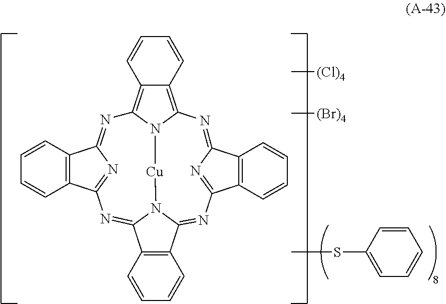

The groups indicated by the abbreviations shown in the above table are groups having the following structures.

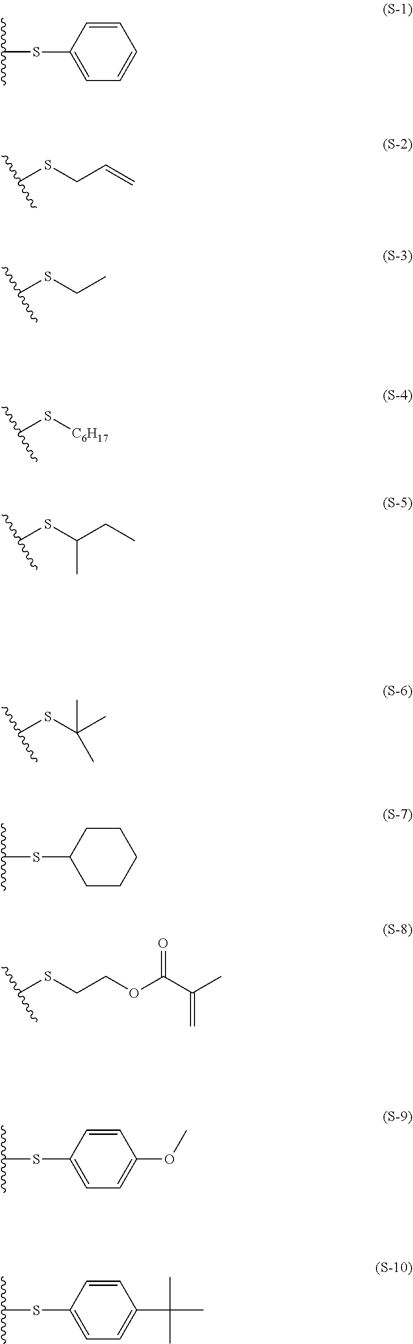

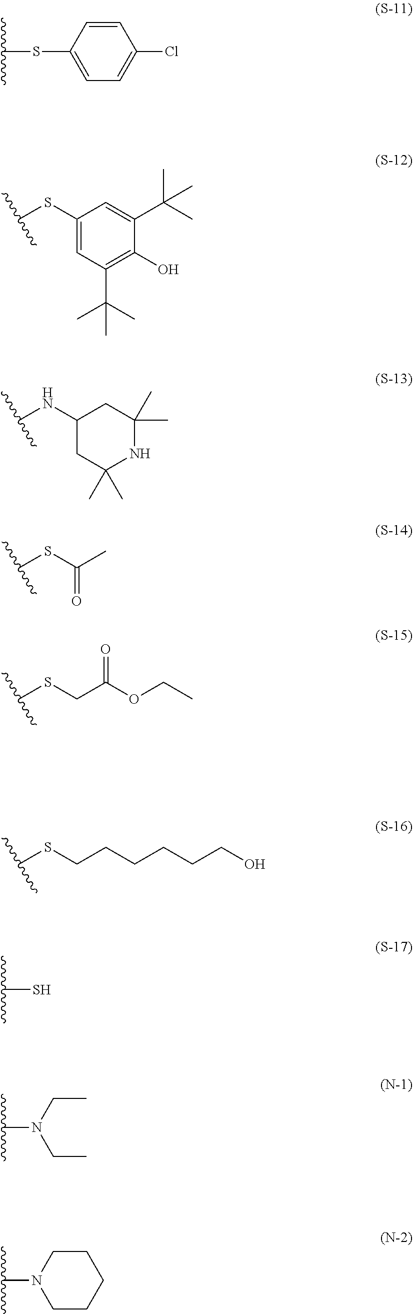

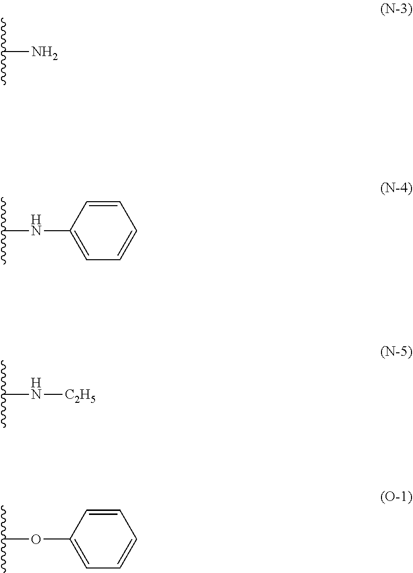

A maximal absorption wavelength of the compound (1) is preferably in a wavelength range of 620 to 730 nm, more preferably in a wavelength range of 635 to 700 nm, and still more preferably in a wavelength range of 650 to 680 nm. The maximal absorption wavelength of the compound (1) can be obtained by diluting the compound (1) with KBr to produce a powder sample (content of the compound (1): 0.001% by mass) and measuring a diffuse-reflect spectrum of the powder sample with an integrating sphere. Examples of a measuring device include an absorption spectroscope V7200 (with an integrating sphere) manufactured by JASCO Corporation.

A solubility of the compound (1) in propylene glycol methyl ether acetate at 25° C. is preferably 500 mg/L or less, more preferably 50 mg/L or less, and still more preferably 10 mg/L or less. The lower limit of the solubility is not particularly limited, but may be, for example, 0.01 mg/L or more. In a case where the solubility of the compound (1) in propylene glycol methyl ether acetate at 25° C. is 500 mg/L or more, the effects of the present invention are remarkably exhibited. Further, heat resistance and light resistance of the obtained film can be improved.

A molecular weight of the compound (1) is preferably 2500 or less, more preferably 2000 or less, and still more preferably 1700 or less. The lower limit is preferably 600 or more. In a case where the molecular weight of the compound (1) is 2500 or less, a molar amount per unit mass increases, so that a high color value can be easily obtained.

The green pigment used in the present invention may include a green pigment (hereinafter, also referred to as other green pigments) other than the above-described compound (1). Examples of the other green pigments include Color Index (C. I.) Pigment Green 7, 10, 36, 37, 58, 59, 62, 63, 64, and 65. In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the other green pigments. Specific examples thereof include the compounds described in WO2015/118720A. In addition, as the other green pigments, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

The coloring composition according to the embodiment of the present invention can further contain a colorant (hereinafter, also referred to as other colorants) other than the green pigment. Examples of the other colorants include yellow colorants, orange colorants, red colorants, violet colorants, and blue colorants. The other colorants may be either a pigment or a dye.

The coloring composition according to the embodiment of the present invention preferably includes a yellow colorant as the other colorants, and more preferably includes a yellow pigment. According to this aspect, it is easy to form a film having spectral characteristics suitable for a green pixel. In addition, the content of the yellow pigment in the coloring composition is preferably 10 to 100 parts by mass with respect to 100 parts by mass of the green pigment. The upper limit is preferably 80 parts by mass or less, more preferably 70 parts by mass or less, and still more preferably 50 parts by mass or less. The lower limit is preferably 12.5 parts by mass or more, more preferably 14 parts by mass or more, and still more preferably 16 parts by mass or more.

Examples of the yellow colorant include an azo compound, a quinophthalone compound, an isoindolinone compound, an isoindoline compound, and an anthraquinone compound. Among these, from the reason that it is easy to form a film having spectral characteristics suitable for a green pixel, an isoindoline compound is preferable.

Examples of the yellow pigment include Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), and 236 (aminoketone-based). In addition, as the yellow pigment, from the viewpoint of improving resistance, it is also preferable to use C. I. Pigment Yellow 129 or C. I. Pigment Yellow 215.

In addition, as the yellow pigment, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, a compound represented by Formula (QP1), and a compound represented by Formula (QP2) can also be used.

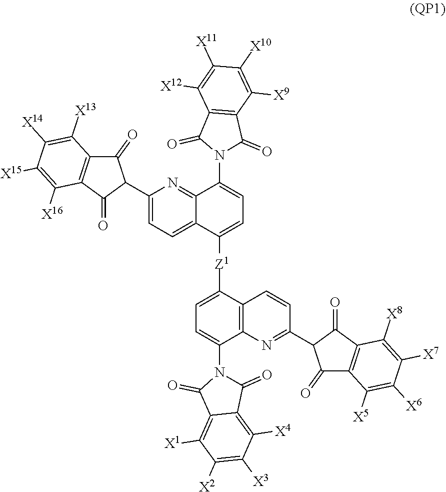

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

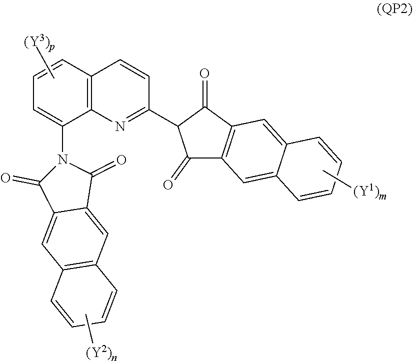

In Formula (QP2), Y¹ to Y3 each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B3.

Examples of the other colorants other than yellow include the following.

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments);

C. I. Pigment Violet 1, 19, 23, 27, 32, 37, 42, 60 (triarylmethane-based), 61 (xanthene-based), and the like (all of which are violet pigments);

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments); and

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments).

In addition, as the blue colorant, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A.

As the red colorant, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, red colorants described in JP6516119B, red colorant described in JP6525101B, and the like can also be used. In addition, as the red colorant, a compound having a structure that an aromatic ring group in which a group bonded with an oxygen atom, a sulfur atom, or a nitrogen atom is introduced to an aromatic ring is bonded to a diketopyrrolopyrrole skeleton can be used.

In addition, a dye can be used as the other colorants. The dye is not particularly limited and a known dye can be used. Examples thereof include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound.

In addition, as the other colorants, thiazole compounds described in JP2012-158649A, azo compounds described in JP2011-184493A, or azo compounds described in JP2011-145540A can also be used.

A content of the colorant in the total solid content of the coloring composition is preferably 25% to 80% by mass. The lower limit is preferably 30% by mass or more, more preferably 40% by mass or more, still more preferably 45% by mass or more, and particularly preferably 50% by mass or more. The upper limit is preferably 75% by mass or less and more preferably 65% by mass or less.

A content of the green pigment in the total solid content of the coloring composition is 25% by mass or more, preferably 30% by mass or more and more preferably 40% by mass or more. Among these, from the reason that film thickness reduction is suppressed, the content of the green pigment in the total solid content of the coloring composition is still more preferably 45% by mass or more and particularly preferably 50% by mass or more. The upper limit is preferably 80% by mass or less, more preferably 75% by mass or less, and still more preferably 70% by mass or less.

A content of the compound (1) in the total solid content of the coloring composition is preferably 5% by mass or more, more preferably 15% by mass or more, and still more preferably 25% by mass or more. The upper limit is preferably 80% by mass or less, more preferably 75% by mass or less, and still more preferably 70% by mass or less.

The content of the green pigment in the colorant is preferably 30% by mass or more, more preferably 50% by mass or more, and still more preferably 70% by mass or more. The upper limit may be 100% by mass, 95% by mass or less, or 90% by mass or less.

The content of the compound (1) in the green pigment is preferably 10% by mass or more, more preferably 20% by mass or more, and still more preferably 30% by mass or more. The upper limit may be 100% by mass, 90% by mass or less, or 80% by mass or less. In addition, it is also preferable that the green pigment is substantially only the compound (1). The case where the green pigment is substantially only the compound (1) means that a proportion of the compound (1) in the total amount of the green pigment is 99% by mass or more, preferably 99.5% by mass or more and more preferably 100% by mass.

In a case where the coloring composition according to the embodiment of the present invention contains a green pigment and a yellow pigment, a total content of the green pigment and the yellow pigment in the colorant is preferably 30% by mass or more, more preferably 40% by mass or more, and still more preferably 50% by mass or more. The upper limit may be 100% by mass, 95% by mass or less, or 90% by mass or less.

In a case where the coloring composition according to the embodiment of the present invention contains a green pigment and a yellow pigment, it is preferable to contain 1 to 60 parts by mass of the yellow pigment with respect to 100 parts by mass of the green pigment. The upper limit is preferably 55 parts by mass or less, more preferably 50 parts by mass or less, and still more preferably 40 parts by mass or less. The lower limit is preferably 5 parts by mass or more, more preferably 10 parts by mass or more, and still more preferably 20 parts by mass or more. In addition, it is preferable to contain 1 to 600 parts by mass of the yellow pigment with respect to 100 parts by mass of the compound (1). The upper limit is preferably 500 parts by mass or less, more preferably 100 parts by mass or less, and still more preferably 50 parts by mass or less. The lower limit is preferably 5 parts by mass or more, more preferably 10 parts by mass or more, and still more preferably 20 parts by mass or more.

<<Pigment Derivative>>

The coloring composition according to the embodiment of the present invention can contain a pigment derivative. According to this aspect, storage stability of the coloring composition can be further improved. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

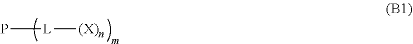

In Formula (B1), P represents a coloring agent structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

Examples of the coloring agent structure represented by P include a pyrrolopyrrole coloring agent structure, a diketopyrrolopyrrole coloring agent structure, a quinacridone coloring agent structure, an anthraquinone coloring agent structure, a dianthraquinone coloring agent structure, a benzoisoindole coloring agent structure, a thiazine indigo coloring agent structure, an azo coloring agent structure, a quinophthalone coloring agent structure, a phthalocyanine coloring agent structure, a naphthalocyanine coloring agent structure, a dioxazine coloring agent structure, a perylene coloring agent structure, a perinone coloring agent structure, a benzimidazolone coloring agent structure, a benzothiazole coloring agent structure, a benzimidazole coloring agent structure, and a benzoxazole coloring agent structure.

Examples of the linking group represented by L include a hydrocarbon group, a heterocyclic group, —NR—, —SO₂—, —S—, —O—, —CO—, or a group of a combination of these groups. R represents a hydrogen atom, an alkyl group, or an aryl group.

Examples of the acid group represented by X include a carboxyl group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR^{X5}, or —SO₂NHCOR^{X6} is preferable. R^{X1} to R^{X6} each independently represent a hydrocarbon group or a heterocyclic group. The hydrocarbon group and heterocyclic group represented by R^{X1} to R^{X6} may further have a substituent. As the substituent which may be further included, a halogen atom is preferable and a fluorine atom is more preferable. Examples of the basic group represented by X include an amino group. Examples of the salt structure represented by X include a salt of the acid group or the basic group described above.

In the present invention, as the pigment derivative, a pigment derivative having excellent visible transparency (hereinafter, also referred to as a transparent pigment derivative) can be contained. The maximum value (Fmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of Fmax is, for example, 1 L·mol⁻¹·cm⁻¹ or more and may be 10 L·mol⁻¹·cm⁻¹ or more.

Specific examples of the pigment derivative include compounds described in Example described later and compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A.

A content of the pigment derivative in the total solid content of the coloring composition is preferably 0.3% to 20% by mass. The lower limit is preferably 0.6% by mass or more and more preferably 0.9% by mass or more. The upper limit is preferably 15% by mass or less, more preferably 1²0.5% by mass or less, and still more preferably 10% by mass or less.

In addition, the content of the pigment derivative is preferably 1 to 40 parts by mass with respect to 100 parts by mass of the green pigment. The lower limit is preferably 5 parts by mass or more and more preferably 10 parts by mass or more. The upper limit is preferably 30 parts by mass or less, more preferably 25 parts by mass or less, and still more preferably 20 parts by mass or less. The pigment derivative may be used singly or in combination of two or more kinds thereof. In a case where two or more kinds thereof are used in combination, the total amount thereof is preferably within the above-described range.

<<Polymerizable Compound>>

The coloring composition according to the embodiment of the present invention contains a polymerizable compound. As the polymerizable compound, a known compound which is cross-linkable by a radical, an acid, or heat can be used. In the present invention, the polymerizable compound is preferably, for example, a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetra(meth)acrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), DPHA-40H (manufactured by Nippon Kayaku Co., Ltd.), UA-306H, UA-306T, UA-306I, AH-600, T-600, AI-600, and LINC-202UA (manufactured by KYOEISHA CHEMICAL Co., LTD.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

In addition, as the polymerizable compound, a compound having an acid group can also be used. By using a polymerizable compound having an acid group, the polymerizable compound in a non-exposed portion is easily removed during development and the generation of a development residue can be suppressed. Examples of the acid group include a carboxy group, a sulfo group, and a phosphoric acid group, and a carboxy group is preferable. Examples of a commercially available product of the polymerizable compound having an acid group include ARONIX M-510, M-520, and ARONIX TO-2349 (manufactured by TOAGOSEI CO., LTD). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

In addition, as the polymerizable compound, a compound having a caprolactone structure can also be used. Examples of a commercially available product of the polymerizable compound having a caprolactone structure include KAYARAD DPCA-20, DPCA-30, DPCA-60, and DPCA-120 (all manufactured by Nippon Kayaku Co., Ltd.).

In addition, as the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 (manufactured by Sartomer), which is a tetrafunctional (meth)acrylate having 4 ethyleneoxy groups, and KAYARAD TPA-330 (manufactured by Nippon Kayaku Co., Ltd.), which is a trifunctional (meth)acrylate having 3 isobutyleneoxy groups.

In addition, as the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

A content of the polymerizable compound in the total solid content of the coloring composition is preferably 0.1% to 50% by mass. The lower limit is more preferably 0.5% by mass or more and still more preferably 1% by mass or more. The upper limit is more preferably 45% by mass or less and still more preferably 40% by mass or less. The polymerizable compound may be used singly or in combination of two or more kinds thereof. In a case where two or more kinds thereof are used in combination, the total thereof is preferably within the above-described range.

<<Photopolymerization Initiator>>

The coloring composition according to the embodiment of the present invention contains a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

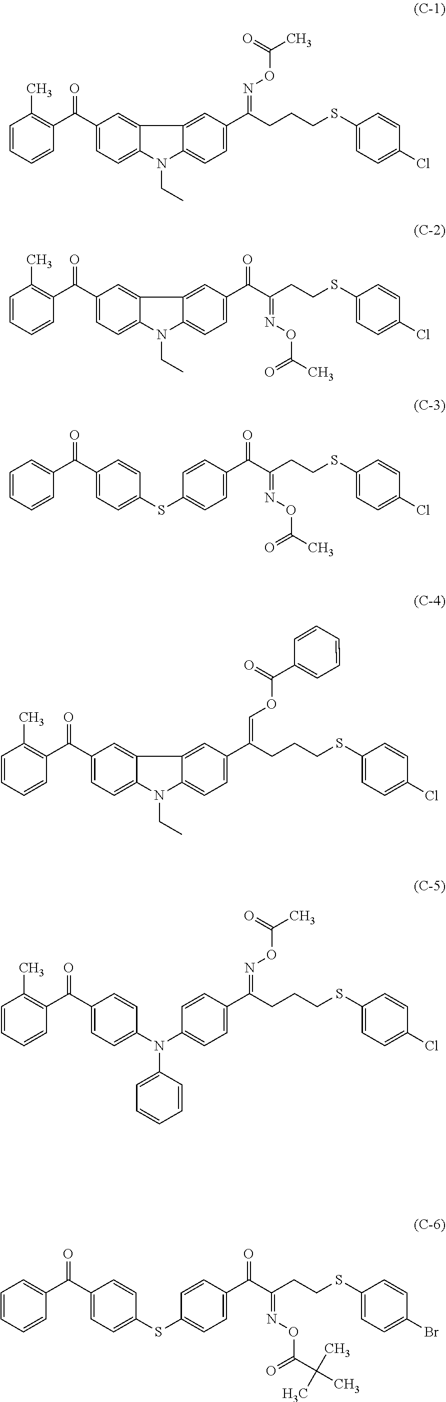 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(=C/OC(=O)c3ccccc3)CCCSc3ccc(Cl)cc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

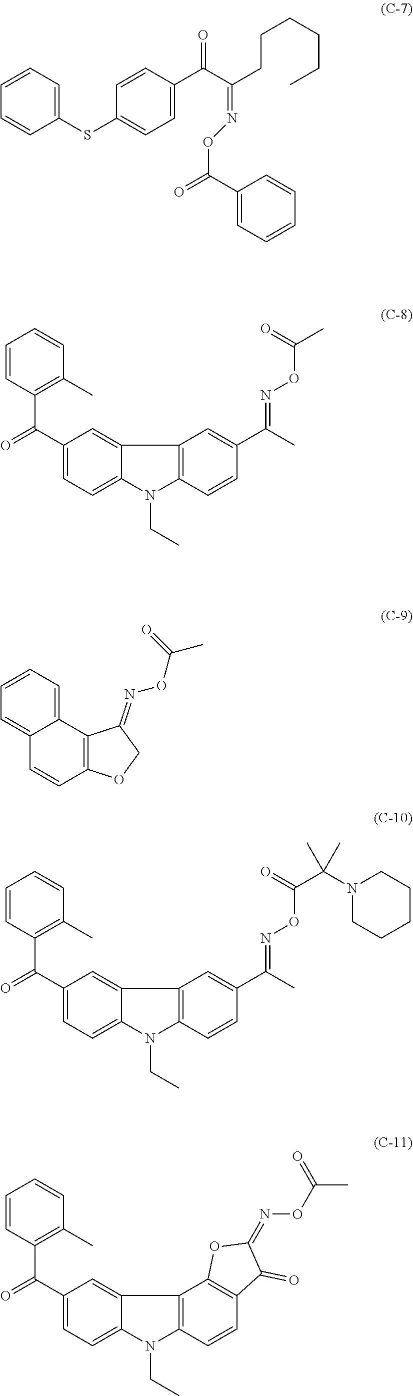 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

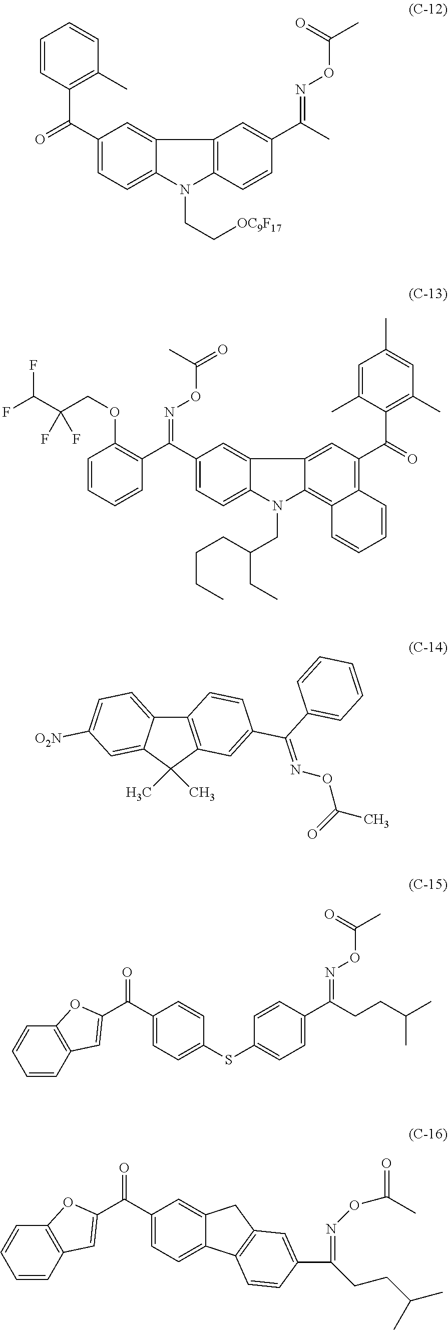

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian) using an ethyl acetate solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

A content of the photopolymerization initiator in the total solid content of the coloring composition is preferably 0.1% to 30% by mass. The lower limit is preferably 0.5% by mass or more and more preferably 1% by mass or more. The upper limit is preferably 20% by mass or less and more preferably 15% by mass or less. In the coloring composition according to the embodiment of the present invention, the photopolymerization initiator may be used singly or in combination of two or more kinds thereof. In a case where two or more kinds thereof are used, the total amount thereof is preferably within the above-described range.

<<Resin>>

The coloring composition according to the embodiment of the present invention can contain a resin. The resin is blended in, for example, an application for dispersing particles such as a pigment in the coloring composition or an application as a binder. Mainly, a resin which is used for dispersing particles such as a pigment is also referred to as a dispersant. However, such applications of the resin are only exemplary, and the resin can also be used for other purposes in addition to such applications.

A weight-average molecular weight (Mw) of the resin is preferably 3000 to 2000000. The upper limit is preferably 1000000 or less and more preferably 500000 or less. The lower limit is preferably 4000 or more and more preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof. In addition, the resins described in paragraph Nos. 0041 to 0060 of JP2017-206689A, and the resins described in paragraph Nos. 0022 to 0071 of JP2018-010856A can also be used.

In the present invention, as the resin, a resin having an acid group can be preferably used. According to this aspect, developability of the coloring composition can be improved, and pixels having excellent rectangularity can be easily formed. Examples of the acid group include a carboxyl group, a phosphoric acid group, a sulfo group, and a phenolic hydroxy group, and a carboxy group is preferable. The resin having an acid group can be used, for example, as an alkali-soluble resin.

The resin having an acid group preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

It is also preferable that the resin having an acid group includes a repeating unit derived from a monomer component including a compound represented by Formula (ED1) and/or a compound represented by Formula (ED2) (hereinafter, these compounds may be referred to as an “ether dimer”).

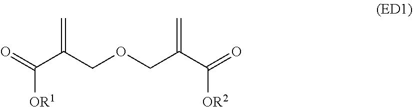

In Formula (ED1). R¹ and R² each independently represent a hydrogen atom or a hydrocarbon group having 1 to 25 carbon atoms, which may have a substituent.

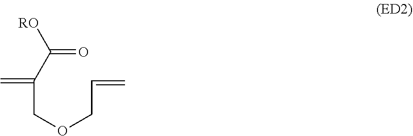

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

With regard to the specific examples of the ether dimer, reference can be made to the description in paragraph No. 0317 of JP2013-029760A, the contents of which are incorporated herein by reference.

It is also preferable that the resin used in the present invention includes a repeating unit derived from a compound represented by Formula (X).

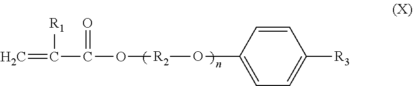

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring. n represents an integer of 1 to 15.

With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. A commercially available product can also be used as the resin having an acid group.

An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. A weight-average molecular weight (Mw) of the resin having an acid group is preferably 5000 to 100000. In addition, a number-average molecular weight (Mn) of the resin having an acid group is preferably 1000 to 20000.

Examples of the resin having an acid group include a resin having the following structures.

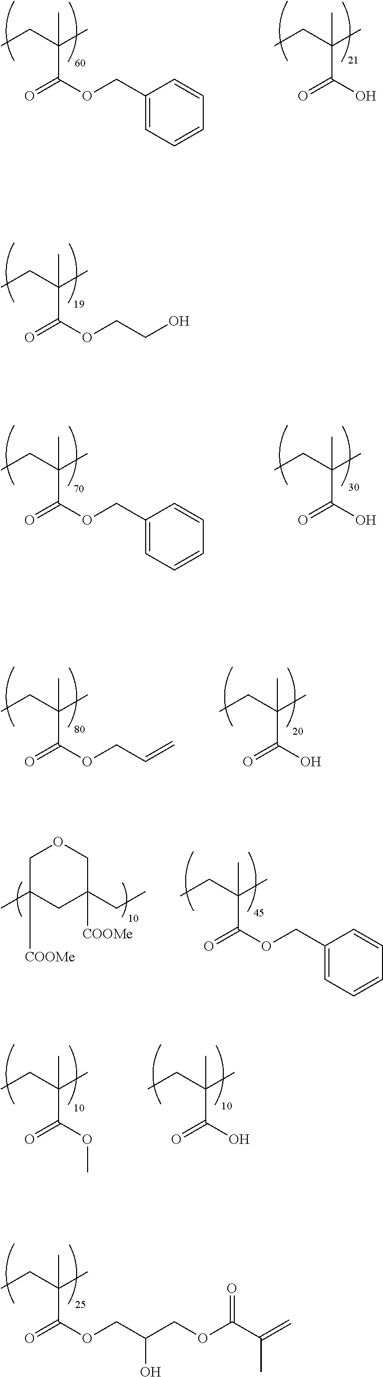

The coloring composition according to the embodiment of the present invention preferably contains a resin having a basic group. The resin having a basic group is preferably a resin including a repeating unit having a basic group in the side chain, more preferably a copolymer having a repeating unit having a basic group in the side chain and a repeating unit not having a basic group, and still more preferably a block copolymer having a repeating unit having a basic group in the side chain and a repeating unit not having a basic group. The resin having a basic group can also be used as a dispersant. An amine value of the resin having a basic group is preferably 5 to 300 mgKOH/g. The lower limit is preferably 10 mgKOH/g or more and more preferably 20 mgKOH/g or more. The upper limit is preferably 200 mgKOH/g or less and more preferably 100 mgKOH/g or less. Examples of the basic group included in the resin having a basic group include a group represented by Formula (a-1) and a group represented by Formula (a-2), and a group represented by Formula (a-2) is preferable.

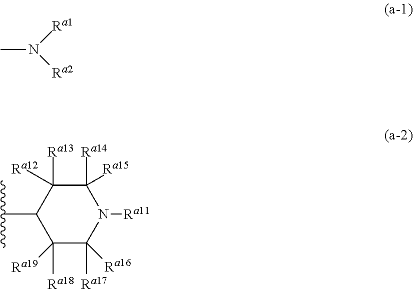

In Formula (a-1), R^{a1} and R^{a2} each independently represent a hydrogen atom, an alkyl group, or an aryl group, and R^{a1} and R^{a2} may be bonded to each other to form a ring; in Formula (a-2), R^{a}n represents a hydrogen atom, a hydroxy group, an alkyl group, an alkoxy group, an aryl group, an aryloxy group, an acyl group, or an oxyradical, and R^{a12} to R^{a19} each independently represent a hydrogen atom, an alkyl group, or an aryl group.

The alkyl group represented by R^{a1}, R^{a2}, R^{a11} to R^{a19} preferably has 1 to 30 carbon atoms, more preferably has 1 to 15 carbon atoms, still more preferably has 1 to 8 carbon atoms, and particularly preferably has 1 to 5 carbon atoms. The alkyl group may be any of linear, branched, and cyclic forms, and is preferably linear or branched and more preferably linear.

The alkyl group may have a substituent. Examples of the substituent include the above-described substituent T.

The aryl group represented by R^{a1}, R^{a2}, R^{a11} to R^{a19} preferably has 6 to 30 carbon atoms, more preferably has 6 to 20 carbon atoms, and still more preferably has 6 to 12 carbon atoms.

The aryl group may have a substituent. Examples of the substituent include the above-described substituent T.

The alkoxy group represented by R^{a11} preferably has 1 to 30 carbon atoms, more preferably has 1 to 15 carbon atoms, still more preferably has 1 to 8 carbon atoms, and particularly preferably has 1 to 5 carbon atoms. The alkoxy group may have a substituent.

Examples of the substituent include the above-described substituent T.

The aryloxy group represented by R^{a11} preferably has 6 to 30 carbon atoms, more preferably has 6 to 20 carbon atoms, and still more preferably has 6 to 12 carbon atoms. The aryloxy group may have a substituent. Examples of the substituent include the above-described substituent T.

The acyl group represented by R^{a11} preferably has 2 to 30 carbon atoms, more preferably has 2 to 20 carbon atoms, and still more preferably has 2 to 12 carbon atoms. The acyl group may have a substituent. Examples of the substituent include the above-described substituent T.

Specific examples of the resin having a basic group include resins (block copolymers) having the following structures. In addition, as the resin having a basic group, a block copolymer (B) described in paragraph Nos. 0063 to 0112 of JP2014-219665A or a block copolymer A1 described in paragraph Nos. 0046 to 0076 of JP2018-156021A, the contents of which are incorporated herein by reference.

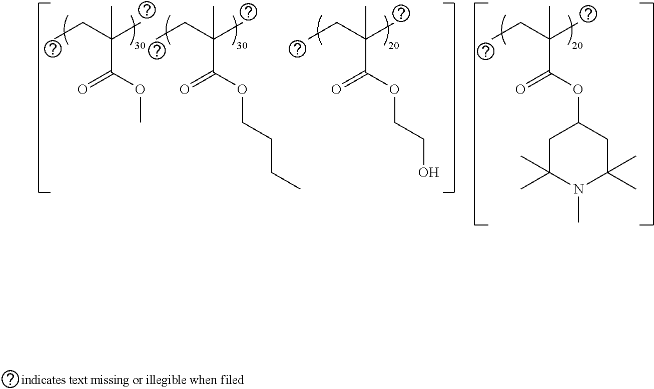

The coloring composition according to the embodiment of the present invention can also contain a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxyl group. The acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

The resin used as a dispersant preferably includes a repeating unit having an acid group. In a case where the resin used as a dispersant includes a repeating unit having an acid group, the generation of the development residue can be further suppressed in the formation of a pattern by a photolithography method.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

In addition, the above-described resin (alkali-soluble resin) having an acid group can also be used as a dispersant.

In addition, it is also preferable that the resin used as a dispersant is a resin including a repeating unit having an ethylenically unsaturated bond-containing group in the side chain. The content of the repeating unit having an ethylenically unsaturated bond-containing group in the side chain is preferably 10 mol % or more, more preferably 10 to 80 mol %, and still more preferably 20 to 70 mol % with respect to the total repeating units of the resin.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. The dispersing agents described in paragraph Nos. 0041 to 0130 of JP2014-130338A can also be used, the contents of which are incorporated herein by reference. The resin described as a dispersant can be used for an application other than the dispersant. For example, the resin can also be used as a binder.

A content of the resin in the total solid content of the coloring composition is preferably 5% to 50% by mass. The lower limit is preferably 10% by mass or more and more preferably 15% by mass or more. The upper limit is preferably 40% by mass or less, more preferably 35% by mass or less, and still more preferably 30% by mass or less. In addition, the content of the resin (alkali-soluble resin) having an acid group in the total solid content of the coloring composition is preferably 5 to 50% by mass. The lower limit is preferably 10% by mass or more and more preferably 15% by mass or more. The upper limit is preferably 40% by mass or less, more preferably 35% by mass or less, and still more preferably 30% by mass or less. In addition, from the reason that excellent developability is easily obtained, the content of the resin (alkali-soluble resin) having an acid group in the total amount of the resin is preferably 30% by mass or more, more preferably 50% by mass or more, still more preferably 70% by mass or more, and particularly preferably 80% by mass or more. The upper limit may be 100% by mass, 95% by mass, or 90% by mass or less.

In addition, from the viewpoint of curing properties, developability, and film-forming property, the total content of the polymerizable compound and resin in the total solid content of the coloring composition is preferably 10% to 65% by mass. The lower limit is preferably 15% by mass or more, more preferably 20% by mass or more, and still more preferably 30% by mass or more. The upper limit is preferably 60% by mass or less, more preferably 50% by mass or less, and still more preferably 40% by mass or less. In addition, the photosensitive composition according to the embodiment of the present invention preferably contains 30 to 300 parts by mass of the resin with respect to 100 parts by mass of the polymerizable compound. The lower limit is preferably 50 parts by mass or more and more preferably 80 parts by mass or more. The upper limit is preferably 250 parts by mass or less and more preferably 200 parts by mass or less.

<<Compound Having Cyclic Ether Group>>

The coloring composition according to the embodiment of the present invention can contain a compound having a cyclic ether group. Examples of the cyclic ether group include an epoxy group and an oxetanyl group. It is preferable that the compound having a cyclic ether group is a compound having an epoxy group (hereinafter, also referred to as an “epoxy compound”). As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the epoxy compound is preferably 200 to 100000 and more preferably 500 to 50000. The upper limit of the weight-average molecular weight is preferably 10000 or less, more preferably 5000 or less, and still more preferably 3000 or less.

As the epoxy compound, an epoxy resin can be preferably used. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation., an epoxy group-containing polymer).

A content of the compound having a cyclic ether group in the total solid content of the coloring composition is preferably 0.1% to 20% by mass. The lower limit is, for example, preferably 0.5% by mass or more and more preferably 1% by mass or more. The upper limit is, for example, preferably 15% by mass or less and still more preferably 10% by mass or less. The compound having a cyclic ether group may be used singly or in combination of two or more kinds thereof. In a case of using two or more kinds thereof, the total amount thereof is preferably within the above-described range.

<<Curing Accelerator>>

The coloring composition according to the embodiment of the present invention may contain a curing accelerator. Examples of the curing accelerator include a thiol compound, a methylol compound, an amine compound, a phosphonium salt compound, an amidine salt compound, an amide compound, a base generator, an isocyanate compound, an alkoxysilane compound, and an onium salt compound. Specific examples of the curing accelerator include compounds described in paragraph Nos. 0094 to 0097 of WO2018/056189A, compounds described in paragraph Nos. 0246 to 0253 of JP2015-034963A, compounds described in paragraph Nos. 0186 to 0251 of JP2013-041165A, ionic compounds described in JP2014-055114A, compounds described in paragraph Nos. 0071 to 0080 of JP2012-150180A, alkoxysilane compounds having an epoxy group described in JP2011-253054A, compounds described in paragraph Nos. 0085 to 0092 of JP5765059B, and carboxy group-containing epoxy curing agent described in JP2017-036379A. A content of the curing accelerator in the total solid content of the coloring composition is preferably 0.3% to 8.9% by mass and more preferably 0.8% to 6.4% by mass.

<<Silane Coupling Agent>>

The coloring composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

A content of the silane coupling agent in the total solid content of the coloring composition is preferably 0.01% to 15.0% by mass and more preferably 0.05% to 10.0% by mass. The silane coupling agent may be used singly or in combination of two or more kinds thereof. In a case of two or more kinds thereof, the total amount thereof is preferably within the above-described range.

<<Organic Solvent>>

The coloring composition according to the embodiment of the present invention contains an organic solvent. Basically, the organic solvent is not particularly limited as long as it satisfies solubility of the respective components and coating properties of the coloring composition. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent substituted with a cyclic alkyl group or a ketone-based solvent substituted with a cyclic alkyl group can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

In the present invention, the organic solvent preferably has the content of peroxides of 0.8 mmol/L or less, and more preferably, the organic solvent does not substantially include peroxides.

A content of the organic solvent in the coloring composition is preferably 10% to 95% by mass, more preferably 20% to 90% by mass, and still more preferably 30% to 90% by mass.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of CHemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition according to the embodiment of the present invention, and may be incorporated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, coloring composition produced by mixing these compounds, or the like.

<<Polymerization Inhibitor>>

The coloring composition according to the embodiment of the present invention can contain a polymerization inhibitor. Examples of the polymerization inhibitor include hydroquinone, p-methoxyphenol, di-tert-butyl-β-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. A content of the polymerization inhibitor in the total solid content of the coloring composition is preferably 0.0001% to 5% by mass.

<<Surfactant>>

The coloring composition according to the embodiment of the present invention can contain a surfactant. As the surfactant, various surfactants such as a fluorine-based surfactant, a nonionic surfactant, a cationic surfactant, an anionic surfactant, and a silicone-based surfactant can be used. With regard to the surfactant, reference can be made to the description in paragraph Nos. 0238 to 0245 of WO2015/166779A, the contents of which are incorporated herein by reference.

In the present invention, it is preferable that the surfactant is a fluorine-based surfactant. By containing a fluorine-based surfactant in the coloring composition, liquid characteristics (particularly, fluidity) are further improved, and liquid saving properties can be further improved. In addition, it is possible to form a film with a small thickness unevenness.

The fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the coloring composition is also good.

Examples of the fluorine-based surfactant include surfactants described in paragraph Nos. 0060 to 0064 of JP2014-041318A (paragraph Nos. 0060 to 0064 of the corresponding WO2014/017669A), and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as the fluorine-based surfactant used in the present invention.

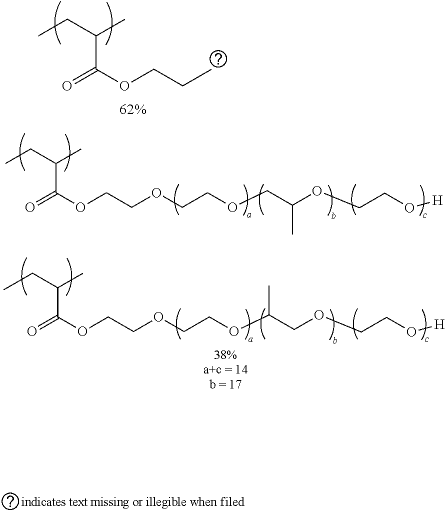

A weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include the compounds described in paragraph Nos. 0050 to 0090 and paragraph Nos. 0289 to 0295 of JP2010-164965A, and for example, MEGAFACE RS-101, RS-102, RS-718K, and RS-72-K manufactured by DIC Corporation. As the fluorine-based surfactant, the compounds described in paragraph Nos. 0015 to 0158 of JP2015-117327A can also be used.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 105, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

A content of the surfactant in the total solid content of the coloring composition is preferably 0.001% by mass to 5.0% by mass and more preferably 0.005% to 3.0% by mass. The surfactant may be used singly or in combination of two or more kinds thereof. In a case of using two or more kinds thereof, the total amount thereof is preferably within the above-described range.

<<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Specific examples of the ultraviolet absorber include a compound having the following structures. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used.

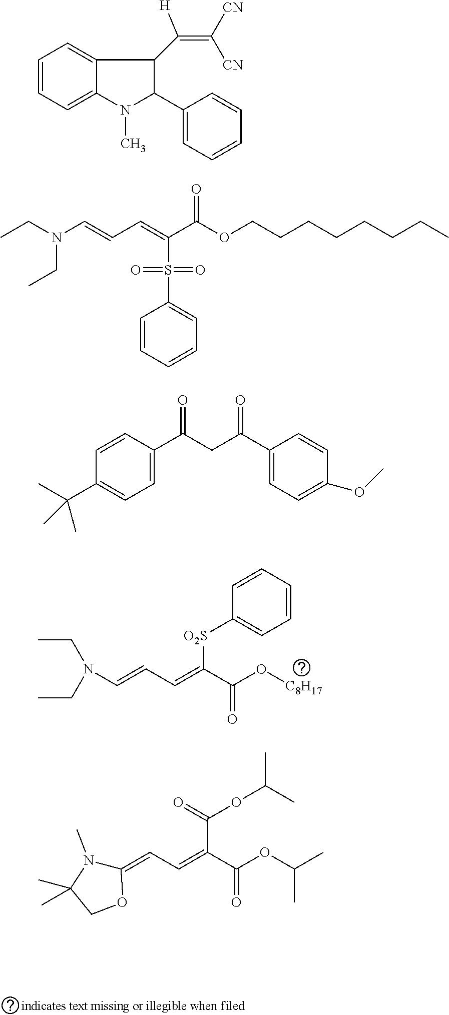

A content of the ultraviolet absorber in the total solid content of the coloring composition is preferably 0.01% to 10% by mass and more preferably 0.01% to 5% by mass. In the present invention, the ultraviolet absorber may be used singly or in combination of two or more kinds thereof. In a case of using two or more kinds thereof, the total amount thereof is preferably within the above-described range.

<<Antioxidant>>

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation). In addition, as the antioxidant, compounds described in paragraph Nos. 0023 to 0048 of JP6268967B can also be used.

A content of the antioxidant in the total solid content of the coloring composition is preferably 0.01% to 20% by mass and more preferably 0.3% to 15% by mass. The antioxidant may be used singly or in combination of two or more kinds thereof. In a case of using two or more kinds thereof, the total amount thereof is preferably within the above-described range.

<<Other Components>>

Optionally, the coloring composition according to the embodiment of the present invention may further contain a sensitizer, a filler, a plasticizer, and other auxiliary agents (for example, conductive particles, an anti-foaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation). In addition, as described in JP2018-155881A, C. I. Pigment Yellow 129 may be added for the purpose of improving weather fastness.

In order to adjust the refractive index of a film to be obtained, the coloring composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The coloring composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

The moisture content in the coloring composition according to the embodiment of the present invention is usually 3% by mass or less, preferably 0.01% to 1.5% by mass and more preferably in a range of 0.1% to 1.0% by mass. The moisture content can be measured by a Karl Fischer method.

The coloring composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a cone plate-type viscometer.

A storage container of the coloring composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A.

<Storage Container>

A storage container of the coloring composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or coloring compositions. Examples of such a container include the containers described in JP2015-123351A.

<Method of Preparing Coloring Composition>

The coloring composition according to the embodiment of the present invention can be prepared by mixing the above-described components with each other. In the preparation of the coloring composition, all the components may be dissolved and/or dispersed at the same time in an organic solvent to prepare the coloring composition, or the respective components may be appropriately left in two or more solutions or dispersion liquids and mixed to prepare the coloring composition upon use (during coating), as desired.

In addition, in the preparation of the coloring composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the preparation of the coloring composition, it is preferable that the coloring composition is filtered through a filter, for example, in order to remove foreign matter or to reduce defects. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers.

As the filter, various filters provided by Nihon Pall Corporation (DFA4201NIEY and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd. In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Film>

A film according to an embodiment of the present invention is a film obtained from the above-described coloring composition according to the embodiment of the present invention. The film according to the embodiment of the present invention can be used for a color filter or the like. Specifically, the film according to the embodiment of the present invention can be preferably used as a colored layer (pixel) of a color filter, and more specifically, and the film according to the embodiment of the present invention can be preferably used as a green-colored layer (green pixel) of a color filter. A thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

<Color Filter>

Next, a color filter according to an embodiment of the present invention will be described. The color filter according to the embodiment of the present invention has the above-described film according to the embodiment of the present invention. More preferably, the color filter according to the embodiment of the present invention has the film according to the embodiment of the present invention as a pixel of the color filter. The color filter according to the embodiment of the present invention can be used for a solid-state imaging element such as a charge coupled device (CCD) and a complementary metal-oxide semiconductor (CMOS), an image display device, or the like.

The color filter according to the embodiment of the present invention may further have a pixel (hereinafter, also referred to as other pixels) different from the film (pixel) according to the embodiment of the present invention. Examples of the other pixels include red pixels, blue pixels, yellow pixels, cyan pixels, magenta pixels, transparent pixels, black pixels, and pixels of near infrared transmitting filter.

In the color filter according to the embodiment of the present invention, a thickness of the film according to the embodiment of the present invention can be appropriately adjusted depending on the purposes. The film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

In the color filter according to the embodiment of the present invention, the width of the pixel is preferably 0.5 to 20.0 μm. The lower limit is preferably 1.0 μm or more and more preferably 2.0 μm or more. The upper limit is preferably 15.0 μm or less and more preferably 10.0 μm or less. In addition, the Young's modulus of the pixel is preferably 0.5 to 20 GPa and more preferably 2.5 to 15 GPa.

Each pixel included in the color filter according to the embodiment of the present invention preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω·cm or more and more preferably 10¹¹ Ω·cm or more. The upper limit is not specified, but is, for example, preferably 10¹⁴ Ω·cm or less. The volume resistivity value of the pixel can be measured, for example, using an ultra-high resistance meter 5410 (manufactured by Advantest Corporation).

The color filter according to the embodiment of the present invention may have a structure in which each pixel is embedded in a space partitioned in, for example, a lattice form by a partition wall.

In addition, in the color filter according to the embodiment of the present invention, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 μm and still more preferably 0.1 to 5 μm.

Examples of a method for forming the protective layer include a method of forming the protective layer by applying a resin composition dissolved in an organic solvent, a chemical vapor deposition method, and a method of attaching a molded resin with an adhesive material.

Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N4, and two or more kinds of these components may be contained. For example, in a case of a protective layer for oxygen shielding, it is preferable that the protective layer contains a polyol resin, SiO₂, and Si₂N4. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. Examples of the ultraviolet absorber and near infrared absorber include the above-described materials. The content of these additives can be appropriately adjusted, but is preferably 0.1% to 70% by mass and still more preferably 1% to 60% by mass with respect to the total weight of the protective layer.

In addition, as the protective layer, the protective layers described in paragraph Nos. 0073 to 0092 of JP2017-151176A can also be used.

<Method for Manufacturing Color Filter>

Next, a method for manufacturing the color filter will be described. The color filter can be manufactured through a step of forming a coloring composition layer on a support using the above-described coloring composition according to the embodiment of the present invention, and a step of forming a pattern on the coloring composition layer by a photolithography method or a dry etching method.

(Photolithography Method)

First, a case of forming a pattern by a photolithography method to manufacture a color filter will be described. Pattern formation by a photolithography method preferably includes a step of forming a coloring composition layer on a support using the coloring composition according to the embodiment of the present invention, a step of exposing the coloring composition layer in a patterned manner, and a step of removing a non-exposed portion of the coloring composition layer by development to form a pattern (pixel). A step (pre-baking step) of baking the coloring composition layer and a step (post-baking step) of baking the developed pattern (pixel) may be provided, optionally.

In the step of forming a coloring composition layer, the coloring composition layer is formed on a support using the coloring composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. The base layer may be formed of a composition obtained by removing a colorant from the coloring composition described in the present specification, a composition including the curable compound, surfactant, and the like described in the present specification, or the like. The surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the resin composition is good. The surface contact angle of the base layer can be adjusted by, for example, adding a surfactant.

As a method of applying the coloring composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet-Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, the contents of which are incorporated herein by reference.

The coloring composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

<<Exposing Step>>

Next, the coloring composition layer is exposed in a patterned manner (exposing step). For example, the coloring composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the coloring composition layer is removed by development to form a pattern (pixel). The non-exposed portion of the coloring composition layer can be removed by development using a developer. Thus, the coloring composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

(Dry Etching Method)

Next, a case of forming a pattern by a dry etching method to manufacture a color filter will be described. Pattern formation by a dry etching method preferably includes a step of forming a coloring composition layer on a support using the coloring composition according to the embodiment of the present invention and curing the entire coloring composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraph Nos. 0010 to 0067 of JP2013-064993A, the content of which is incorporated herein by reference.

<Solid-State Imaging Element>

A solid-state imaging element according to an embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice form by a partition wall. The partition wall in this case preferably has a low refractive index for each colored pixel. Examples of an imaging device having such a structure include the devices described in JP2012-227478A, JP2014-179577A, and WO2018/043654A. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

### (Synthesis Example 1) Synthesis of Compound (A-1)

A compound (A-1) was synthesized according to the following scheme.

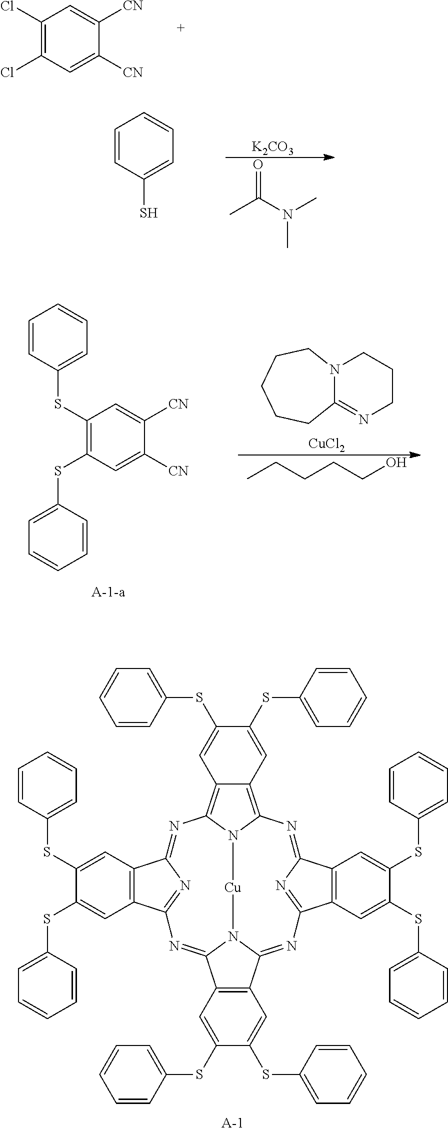

1.0 part by mass of dichlorophthalonitrile, 2.1 parts by mass of potassium carbonate, and 12.5 parts by mass of dimethylacetamide were mixed and stirred. After cooling the solution in a water bath, 1.17 parts by mass of thiophenol was added to the solution. After completion of the addition, the mixture was stirred for 12 hours. After confirming the completion of the reaction, the reaction solution was added dropwise to 20 parts by mass of cold water. The precipitated crystals were separated by filtration, and washed with 20 parts by mass of distilled water. The obtained crystals were blast-dried at 50° C. for 12 hours to obtain 1.57 parts by mass of a compound (A-1-a). ¹H-NMR (heavy dimethyl sulfoxide (DMSO)): δ 7.56 (m, 10H), 7.31 (s, 2H)

1.0 part by mass of the compound (A-1-a) and 30 parts by mass of 1-pentanol were mixed and stirred. After stirring, the mixture was heated under reflux to remove azeotropic water. After cooling the reactor, 0.39 parts by mass of copper chloride and 2.21 parts by mass of diazabicycloundecene were added thereto. The temperature of the reactor was raised, and the mixture was heated under reflux for 2 hours. After completion of the reaction, the mixture was cooled, and 30 parts by mass of methanol was added thereto. The precipitated crystals were separated by filtration, and washed with 30 parts by mass of acetone. The obtained crystals were blast-dried at 50° C. for 12 hours to obtain 0.52 parts by mass of a compound (A-1). A peak with a molecular weight of 1441.35 was observed by Matrix Assisted Laser Desorption/Ionization-Mass Spectrometry (MALDI-MS) to identify the resultant as the compound (A-1).

<Preparation of Dispersion Liquid>

Raw materials described in the following tables were mixed, and then 230 parts by mass of zirconia beads having a diameter of 0.3 mm were added thereto to perform a dispersion treatment for 5 hours using a paint shaker. The beads were separated by filtration, and a pigment dispersion liquid was produced. Numerical values indicating the quantities described in the tables below are parts by mass. In the following, for those described as “Yes” in the column for the presence or absence of the kneading and polishing treatment, a colorant or an infrared absorber which had been kneaded and polished by the following method was used.

(Kneading and Polishing Treatment Conditions)

5.3 parts by mass of a pigment, 74.7 parts by mass of a grinding agent, and 14 parts by mass of a binding agent were added to Labo Plastomill (manufactured by Toyo Seiki Seisaku-sho, Ltd.), the temperature of a kneaded material in the device was controlled to 70° C., and kneading was performed for 2 hours. As the pigment, a material described in the column of the type of green pigment described in the tables below or a material described in the column of yellow pigment described in the tables below was used. As the grinding agent, neutral mirabilite anhydride E (average particle diameter (50% diameter (D50) based on volume)=20 μm, manufactured by Mitajiri Chemical Industry Co., Ltd.) was used. As the binding agent, diethylene glycol was used. The kneaded material after kneading and polishing was washed with 10 L of water at 24° C. to remove the grinding agent and the binding agent, and then treated in a heating oven at 80° C. for 24 hours.

TABLE 2

| | Composition of dispersion liquid | | | | | | | | | | | | | |
|---|---|---|---|---|---|---|---|---|---|---|---|---|---|---|
| | Green pigment | | | Yellow pigment | | | | | | | | | | |
| | | Presence or | | | Presence or | | Pigment | | | | | | Polymerization | |
| | | absence of | | | absence of | | derivative | | Dispersant | | Solvent | | inhibitor | |
| | | kneading and | Part | | kneading and | Part | | Part | | Part | | Part | | Part |
| | | polishing | by | | polishing | by | | by | | by | | by | | by |
| Dispersion liquid | Type | treatment | mass | Type | treatment | mass | Type | mass | Type | mass | Type | mass | Type | mass |
| Dispersion liquid 1 | A-1 | Yes | 9.00 | PY150 | Yes | 2.65 | B1 | 1.32 | D1 | 3.00 | S1 | 84.03 | — | 0 |
| Dispersion liquid 2 | A-2 | Yes | 9.00 | PY150 | Yes | 2.65 | B1 | 1.32 | D1 | 3.00 | S1 | 84.03 | — | 0 |
| Dispersion liquid 3 | A-3 | Yes | 9.00 | PY150 | Yes | 2.65 | B1 | 1.32 | D1 | 3.00 | S1 | 84.03 | — | 0 |
| Dispersion liquid 4 | A-4 | Yes | 9.00 | PY150 | Yes | 2.65 | B1 | 1.32 | D1 | 3.00 | S1 | 84.03 | — | 0 |
| Dispersion liquid 5 | A-6 | Yes | 9.00 | PY150 | Yes | 2.65 | B1 | 1.32 | D1 | 3.00 | S1 | 84.03 | — | 0 |
| Dispersion liquid 6 | A-7 | Yes | 9.00 | PY150 | Yes | 2.65 | B1 | 1.32 | D1 | 3.00 | S1 | 84.03 | — | 0 |
| Dispersion liquid 7 | A-8 | Yes | 9.00 | PY150 | Yes | 2.65 | B1 | 1.32 | D1 | 3.00 | S1 | 84.03 | — | 0 |
| Dispersion liquid 8 | A-9 | Yes | 9.00 | PY150 | Yes | 2.65 | B1 | 1.32 | D1 | 3.00 | S1 | 84.03 | — | 0 |
| Dispersion liquid 9 | A-10 | Yes | 9.00 | PY150 | Yes | 2.65 | B1 | 1.32 | D1 | 3.00 | S1 | 84.03 | — | 0 |
| Dispersion liquid 10 | A-11 | Yes | 9.00 | PY150 | Yes | 2.65 | B1 | 1.32 | D1 | 3.00 | S1 | 84.03 | — | 0 |
| Dispersion liquid 11 | A-12 | Yes | 9.00 | PY150 | Yes | 2.65 | B1 | 1.32 | D1 | 3.00 | S1 | 84.03 | — | 0 |
| Dispersion liquid 12 | A-13 | Yes | 9.00 | PY150 | Yes | 2.65 | B1 | 1.32 | D1 | 3.00 | S1 | 84.03 | — | 0 |
| Dispersion liquid 13 | A-14 | Yes | 9.00 | PY150 | Yes | 2.65 | B1 | 1.32 | D1 | 3.00 | S1 | 84.03 | — | 0 |
| Dispersion liquid 14 | A-16 | Yes | 9.00 | PY150 | Yes | 2.65 | B1 | 1.32 | D1 | 3.00 | S1 | 84.03 | — | 0 |
| Dispersion liquid 15 | A-17 | Yes | 9.00 | PY150 | Yes | 2.65 | B1 | 1.32 | D1 | 3.00 | S1 | 84.03 | — | 0 |
| Dispersion liquid 16 | A-18 | Yes | 9.00 | PY150 | Yes | 2.65 | B1 | 1.319 | D1 | 3.00 | S1 | 84.03 | H1 | 0.001 |
| Dispersion liquid 17 | A-19 | Yes | 9.00 | PY150 | Yes | 2.65 | B1 | 1.319 | D1 | 3.00 | S1 | 84.03 | H1 | 0.001 |
| Dispersion liquid 18 | A-21 | Yes | 9.00 | PY150 | Yes | 2.65 | B1 | 1.32 | D1 | 3.00 | S1 | 84.03 | — | 0 |
| Dispersion liquid 19 | A-23 | Yes | 9.00 | PY150 | Yes | 2.65 | B1 | 1.32 | D1 | 3.00 | S1 | 84.03 | — | 0 |
| Dispersion liquid 20 | A-24 | Yes | 9.00 | PY150 | Yes | 2.65 | B1 | 1.32 | D1 | 3.00 | S1 | 84.03 | — | 0 |
| Dispersion liquid 21 | A-25 | Yes | 9.00 | PY150 | Yes | 2.65 | B1 | 1.32 | D1 | 3.00 | S1 | 84.03 | — | 0 |
| Dispersion liquid 22 | A-26 | Yes | 9.00 | PY150 | Yes | 2.65 | B1 | 1.32 | D1 | 3.00 | S1 | 84.03 | — | 0 |
| Dispersion liquid 23 | A-27 | Yes | 9.00 | PY150 | Yes | 2.65 | B1 | 1.32 | D1 | 3.00 | S1 | 84.03 | — | 0 |
| Dispersion liquid 24 | A-29 | Yes | 9.00 | PY150 | Yes | 2.65 | B1 | 1.32 | D1 | 3.00 | S1 | 84.03 | — | 0 |
| Dispersion liquid 25 | A-32 | Yes | 9.00 | PY150 | Yes | 2.65 | B1 | 1.32 | D1 | 3.00 | S1 | 84.03 | — | 0 |
| Dispersion liquid 26 | A-34 | Yes | 9.00 | PY150 | Yes | 2.65 | B1 | 1.32 | D1 | 3.00 | S1 | 84.03 | — | 0 |
| Dispersion liquid 27 | A-37 | Yes | 9.00 | PY150 | Yes | 2.65 | B1 | 1.32 | D1 | 3.00 | S1 | 84.03 | — | 0 |
| Dispersion liquid 28 | A-41 | Yes | 9.00 | PY150 | Yes | 2.65 | B1 | 1.32 | D1 | 3.00 | S1 | 84.03 | — | 0 |
| Dispersion liquid 29 | A-42 | Yes | 9.00 | PY150 | Yes | 2.65 | B1 | 1.32 | D1 | 3.00 | S1 | 84.03 | — | 0 |
| Dispersion liquid 30 | A-43 | Yes | 9.00 | PY150 | Yes | 2.65 | B1 | 1.32 | D1 | 3.00 | S1 | 84.03 | — | 0 |
| Dispersion liquid 31 | A-45 | Yes | 9.00 | PY150 | Yes | 2.65 | B1 | 1.32 | D1 | 3.00 | S1 | 84.03 | — | 0 |
| Dispersion liquid 32 | A-1 | No | 9.00 | PY185 | Yes | 2.65 | B1 | 1.32 | D1 | 3.00 | S1 | 84.03 | — | 0 |
| Dispersion liquid 33 | A-1 | Yes | 5.00 | PY150 | Yes | 2.65 | B1 | 1.32 | D1 | 3.00 | S1 | 84.03 | — | 0 |
| | A-25 | | 4.00 | | | | | | | | | | | |
| Dispersion liquid 34 | A-1 | Yes | 6.30 | PY150 | Yes | 2.65 | B1 | 1.32 | D1 | 3.00 | S1 | 84.03 | — | 0 |
| | PG36 | | 2.70 | | | | | | | | | | | |
| Dispersion liquid 35 | A-1 | Yes | 6.30 | PY150 | Yes | 2.65 | B1 | 1.32 | D1 | 3.00 | S1 | 84.03 | — | 0 |
| | PG58 | | 2.70 | | | | | | | | | | | |

TABLE 3

| | Composition of dispersion liquid | | | | | | | | | | | | | |
|---|---|---|---|---|---|---|---|---|---|---|---|---|---|---|
| | Green pigment | | | Yellow pigment | | | | | | | | | | |
| | | Presence or | | | Presence or | | Pigment | | | | | | Polymerization | |
| | | absence of | | | absence of | | derivative | | Dispersant | | Solvent | | inhibitor | |
| | | kneading and | Part | | kneading and | Part | | Part | | Part | | Part | | Part |
| | | polishing | by | | polishing | by | | by | | by | | by | | by |
| Dispersion liquid | Type | treatment | mass | Type | treatment | mass | Type | mass | Type | mass | Type | mass | Type | mass |
| Dispersion liquid 36 | A-1 | Yes | 1.75 | PY150 | Yes | 2.65 | B1 | 1.32 | D1 | 3.00 | S1 | 84.03 | — | 0 |
| | PG58 | | 7.25 | | | | | | | | | | | |
| Dispersion liquid 37 | A-1 | Yes | 9.00 | PY185 | Yes | 2.65 | B1 | 1.32 | D1 | 3.00 | S1 | 84.03 | — | 0 |
| Dispersion liquid 38 | A-1 | Yes | 9.00 | PY138 | Yes | 2.65 | B1 | 1.32 | D1 | 3.00 | S1 | 84.03 | — | 0 |
| Dispersion liquid 39 | A-1 | Yes | 9.00 | PY139 | Yes | 2.65 | B1 | 1.32 | D1 | 3.00 | S1 | 84.03 | — | 0 |
| Dispersion liquid 40 | A-1 | Yes | 9.00 | PY129 | Yes | 2.65 | B1 | 1.32 | D1 | 3.00 | S1 | 84.03 | — | 0 |
| Dispersion liquid 41 | A-1 | Yes | 9.00 | PY215 | Yes | 2.65 | B1 | 1.32 | D1 | 3.00 | S1 | 84.03 | — | 0 |
| Dispersion liquid 42 | A-1 | Yes | 9.00 | Y1 | Yes | 2.65 | B1 | 1.32 | D1 | 3.00 | S1 | 84.03 | — | 0 |
| Dispersion liquid 43 | A-1 | Yes | 9.00 | Y2 | Yes | 2.65 | B1 | 1.32 | D1 | 3.00 | S1 | 84.03 | — | 0 |
| Dispersion liquid 44 | A-1 | Yes | 9.00 | PY150 | Yes | 2.65 | B1 | 1.32 | D1 | 3.00 | S1 | 84.03 | — | 0 |
| | | | | PY129 | | | | | | | | | | |
| Dispersion liquid 45 | A-1 | Yes | 9.00 | PY185 | Yes | 2.65 | B1 | 1.32 | D1 | 3.00 | S1 | 84.03 | — | 0 |
| | | | | PY150 | | | | | | | | | | |
| | | | | PY129 | | | | | | | | | | |
| Dispersion liquid 46 | A-1 | Yes | 9.00 | PY150 | No | 2.65 | B1 | 1.32 | D1 | 3.00 | S1 | 84.03 | — | 0 |
| Dispersion liquid 47 | A-1 | Yes | 11.65 | — | — | 0 | B1 | 1.32 | D1 | 3.00 | Si | 84.03 | — | 0 |
| Dispersion liquid 48 | A-1 | Yes | 9.00 | PY150 | Yes | 2.65 | B2 | 1.32 | D1 | 3.00 | S1 | 84.03 | — | 0 |
| Dispersion liquid 49 | A-1 | Yes | 9.00 | PY150 | Yes | 2.65 | B3 | 1.32 | D6 | 3.00 | S1 | 84.03 | — | 0 |
| Dispersion liquid 50 | A-1 | Yes | 9.00 | PY150 | Yes | 2.65 | B4 | 1.32 | D1 | 3.00 | S1 | 84.03 | — | 0 |
| Dispersion liquid Si | A-1 | Yes | 9.00 | PY150 | Yes | 2.65 | B5 | 1.32 | D1 | 3.00 | S1 | 84.03 | — | 0 |
| Dispersion liquid 52 | A-1 | Yes | 9.00 | PY150 | Yes | 2.65 | B6 | 1.32 | D1 | 3.00 | S1 | 84.03 | — | 0 |
| Dispersion liquid 53 | A-1 | Yes | 9.00 | PY150 | Yes | 2.65 | B7 | 1.32 | D1 | 3.00 | S1 | 84.03 | — | 0 |
| Dispersion liquid 54 | A-1 | Yes | 10.00 | PY150 | Yes | 2.65 | — | 0 | D10 | 3.32 | S1 | 84.03 | — | 0 |
| Dispersion liquid 55 | A-1 | Yes | 9.00 | PY150 | Yes | 2.65 | B2 | 1.00 | D1 | 3.00 | S1 | 84.03 | — | 0 |
| | | | | | | | B4 | 0.32 | | | | | | |
| Dispersion liquid 56 | A-1 | Yes | 9.00 | PY150 | Yes | 2.65 | B1 | 1.32 | D4 | 3.00 | S1 | 84.03 | — | 0 |
| Dispersion liquid 57 | A-1 | Yes | 9.00 | PY150 | Yes | 2.65 | B1 | 1.319 | D5 | 3.00 | S1 | 84.03 | H1 | 0.001 |
| Dispersion liquid 58 | A-1 | Yes | 9.00 | PY150 | Yes | 2.65 | B1 | 1.32 | D7 | 3.00 | S1 | 84.03 | — | 0 |
| Dispersion liquid 59 | A-1 | Yes | 9.00 | PY150 | Yes | 2.65 | B1 | 1.32 | D9 | 3.00 | S1 | 84.03 | — | 0 |
| Dispersion liquid 60 | A-1 | Yes | 9.00 | PY150 | Yes | 2.65 | B1 | 1.32 | D10 | 3.00 | S1 | 84.03 | — | 0 |
| Dispersion liquid 61 | A-1 | Yes | 9.00 | PY150 | Yes | 2.65 | B1 | 1.32 | D11 | 3.00 | S1 | 84.03 | — | 0 |
| Dispersion liquid 62 | A-1 | Yes | 9.00 | PY150 | Yes | 2.65 | B1 | 1.32 | D1 | 3.00 | S1 | 84.03 | — | 0 |
| | | | | | | | | | D3 | | | | | |
| Dispersion liquid 63 | A-1 | Yes | 9.00 | PY150 | Yes | 2.65 | B1 | 1.32 | D1 | 3.00 | S2 | 84.03 | — | 0 |
| Dispersion liquid 64 | A-1 | Yes | 9.00 | PY150 | Yes | 2.65 | B1 | 1.32 | D1 | 3.00 | S3 | 84.03 | — | 0 |
| Dispersion liquid 65 | A-1 | Yes | 9.00 | PY150 | Yes | 2.65 | B1 | 1.32 | D1 | 3.00 | S4 | 84.03 | — | 0 |
| Dispersion liquid 66 | A-1 | Yes | 9.00 | PY150 | Yes | 2.65 | B1 | 1.32 | D1 | 3.00 | S5 | 84.03 | — | 0 |
| Dispersion liquid 67 | A-1 | Yes | 9.00 | PY150 | Yes | 2.65 | B1 | 1.32 | D1 | 3.00 | S6 | 84.03 | — | 0 |
| Dispersion liquid 68 | A-1 | Yes | 9.00 | PY150 | Yes | 2.65 | B1 | 1.32 | D1 | 3.00 | S1 | 84.03 | — | 0 |
| | | | | | | | | | | | S2 | | | |
| Dispersion liquid 69 | A-1 | Yes | 22.00 | PY150 | Yes | 2.65 | B1 | 1.00 | D1 | 4.35 | S1 | 70 | — | 0 |
| Dispersion liquid 70 | A-1 | Yes | 11.45 | PY150 | Yes | 2.65 | B1 | 1.32 | D1 | 3.58 | S1 | 81 | — | 0 |
| Dispersion liquid 71 | A-1 | Yes | 7.11 | PY150 | Yes | 2.65 | B1 | 1.32 | D1 | 4.58 | S1 | 84.34 | — | 0 |
| Dispersion liquid 72 | A-1 | Yes | 6.50 | PY150 | Yes | 2.65 | B1 | 1.32 | D1 | 6.00 | S1 | 83.53 | — | 0 |
| Dispersion liquid 73 | A-1 | Yes | 3.58 | PY150 | Yes | 2.65 | B1 | 1.32 | D1 | 3.00 | S1 | 89.45 | — | 0 |
| Dispersion liquid 74 | A-1 | Yes | 9.00 | PY150 | Yes | 1.65 | B1 | 2.32 | D1 | 3.00 | S1 | 84.03 | — | 0 |
| Comparative | a-1 | Yes | 9.00 | PY150 | Yes | 2.65 | B1 | 1.32 | D1 | 3.00 | S1 | 84.03 | — | 0 |
| dispersion liquid 1 | | | | | | | | | | | | | | |

Details of the materials indicated by the abbreviations in the above table are as follows.

(Green Pigment)

A-1, A-2, A-3, A-4, A-6, A-7, A-8, A-9, A-10, A-li, A-12, A-13, A-14, A-16, A-17, A-18, A-19, A-21, A-23, A-24, A-25, A-26, A-27, A-29, A-32, A-34, A-37, A-41, A-42, A-43, A-45: compounds having the structures described in the specific examples of the compound (1) described above; all of these compounds had a maximal absorption wavelength in a wavelength range of 620 to 730 nm, and had a solubility in propylene glycol methyl ether acetate at 25° C. of 500 mg/L or less.

PG36: C. I. Pigment Green 36

PG58: C. I. Pigment Green 58

a-1: compound having the following structure

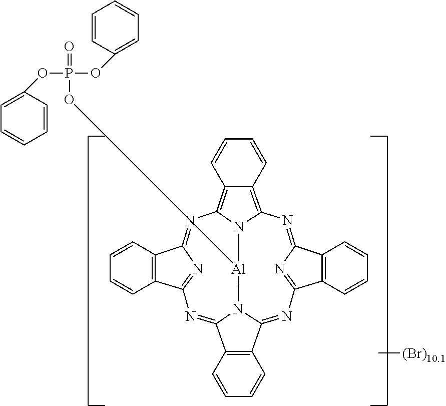

The maximal absorption wavelength of the green pigment was obtained by diluting each green pigment with KBr to produce a powder sample (content of the green pigment: 0.001% by mass) and measuring a diffuse-reflect spectrum of the powder sample with an integrating sphere. As a measuring device, an absorption spectroscope V7200 (with an integrating sphere) manufactured by JASCO Corporation was used.

In addition, the above-described solubility of the green pigment was measured using an integrating sphere turbidity meter (SEP-PT-706D, manufactured by Mitsubishi Chemical Analytech). In a case where the measured value of the turbidity of the sample solution was 1 ppm by mass or less, it was determined that the green pigment was dissolved in the sample solution, and the maximum concentration of the sample solution was defined as the solubility.

(Yellow pigment)

PY129: C. I. Pigment Yellow 129

PY138: C. I. Pigment Yellow 138

PY139: C. I. Pigment Yellow 139

PY150: C. I. Pigment Yellow 150

PY185: C. I. Pigment Yellow 185

PY215: C. I. Pigment Yellow 215

Y1, Y2: compounds having the following structures

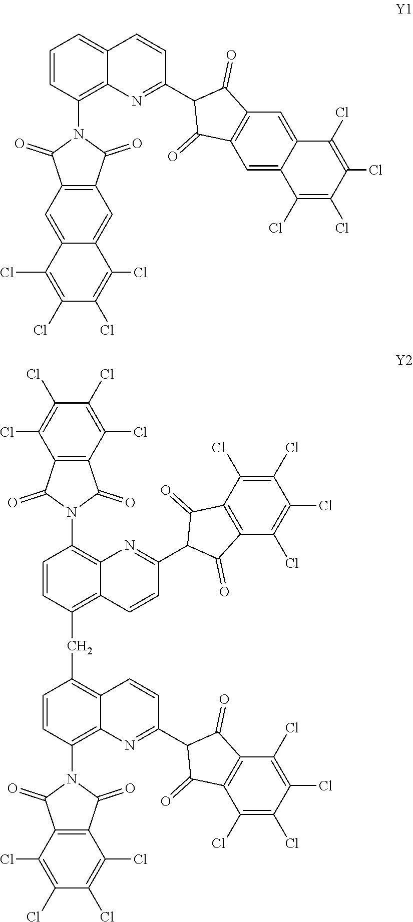

(Pigment Derivative)

B1 to B37: compounds having the following structures

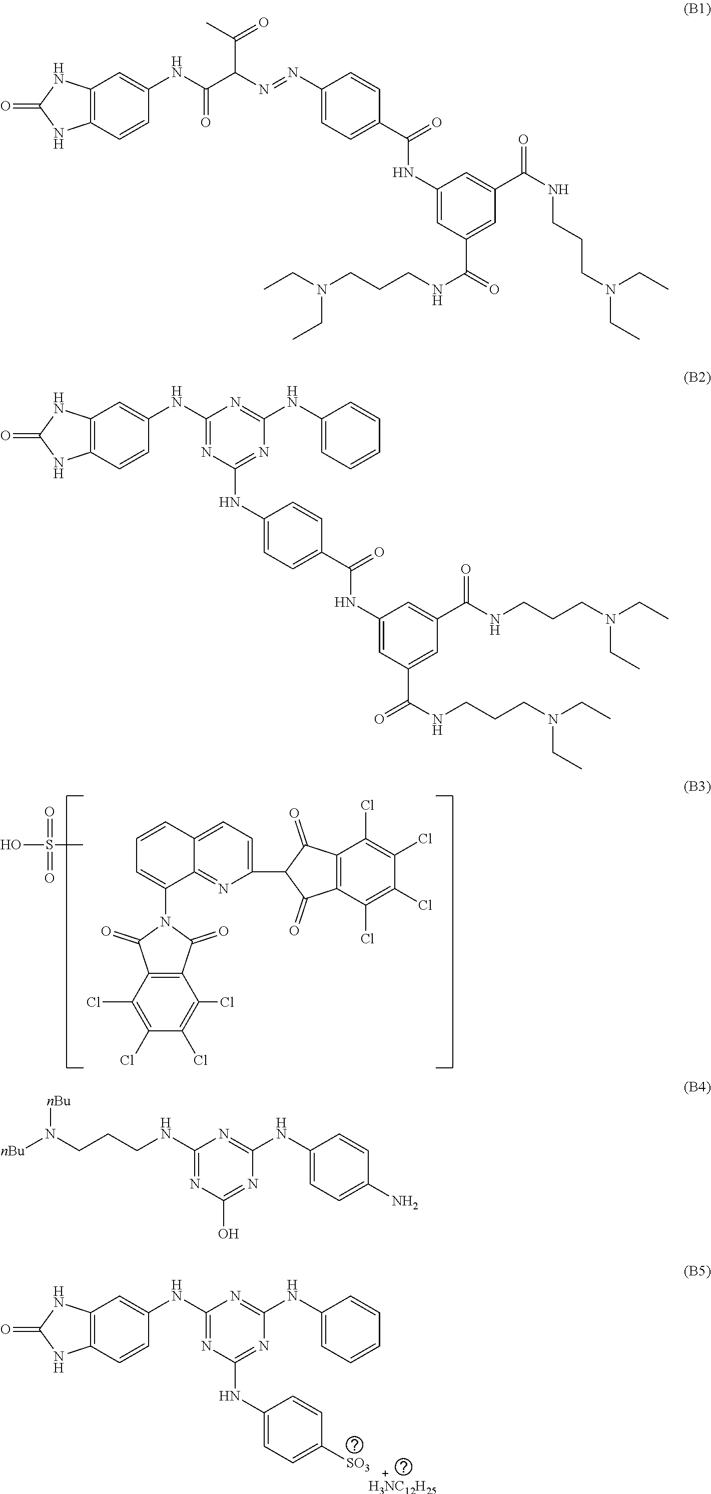

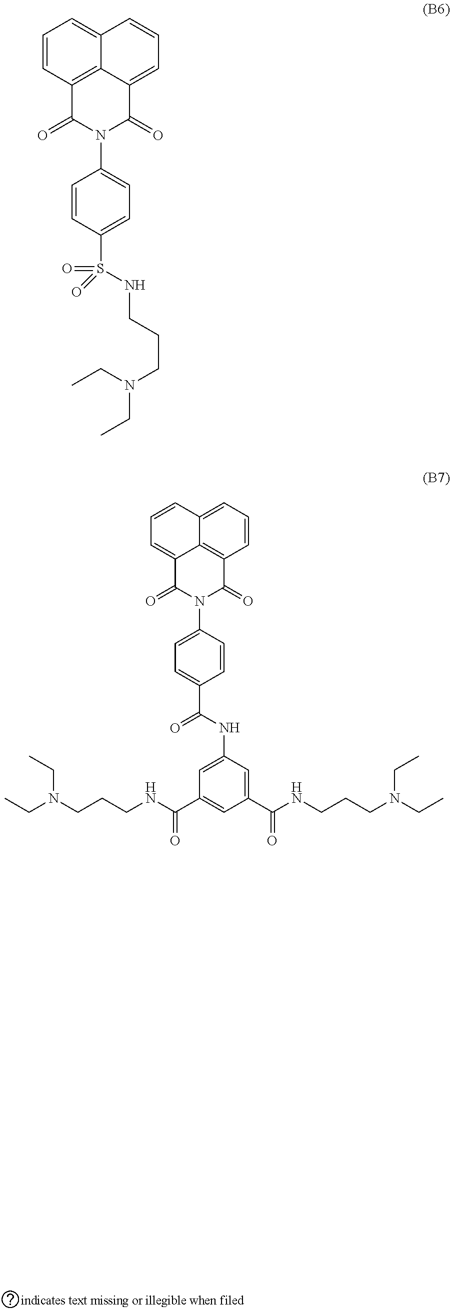 [SMILES: CCN(CC)CCCNS(=O)(=O)c1ccc(N2C(=O)c3cccc4cccc(c34)C2=O)cc1 ; CCN(CC)CCCNC(=O)c1cc(NC(=O)c2ccc(N3C(=O)c4cccc5cccc(c45)C3=O)cc2)cc(C(=O)NCCCN(CC)CC)c1]

(Dispersant)

D1: resin having the following structure (the numerical value described together with the main chain indicates a molar ratio, and the numerical value described together with the side chain indicates the number of repeating units; Mw=24000)

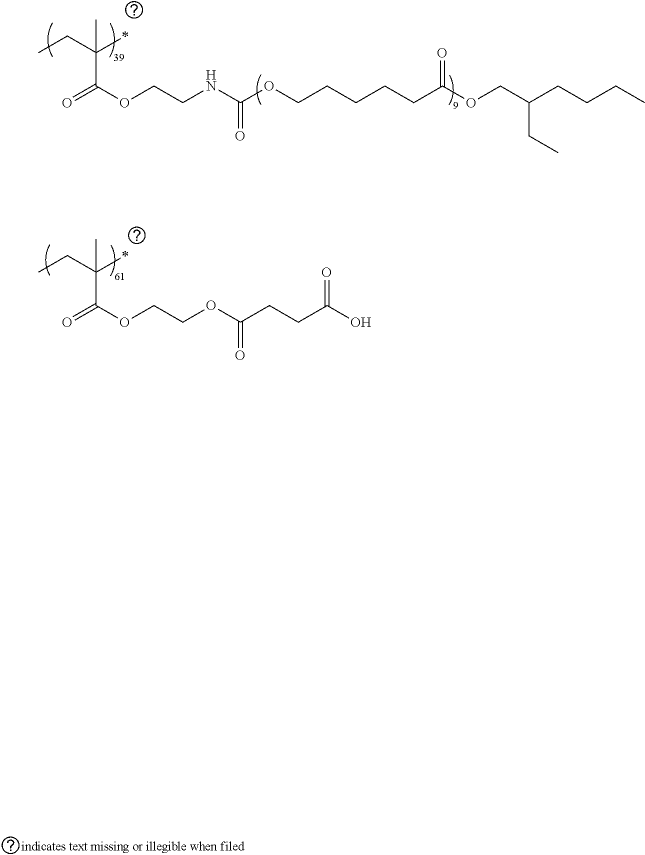

D3: resin having the following structure (the numerical value described together with the main chain indicates a molar ratio, and the numerical value described together with the side chain indicates the number of repeating units; Mw=17000)

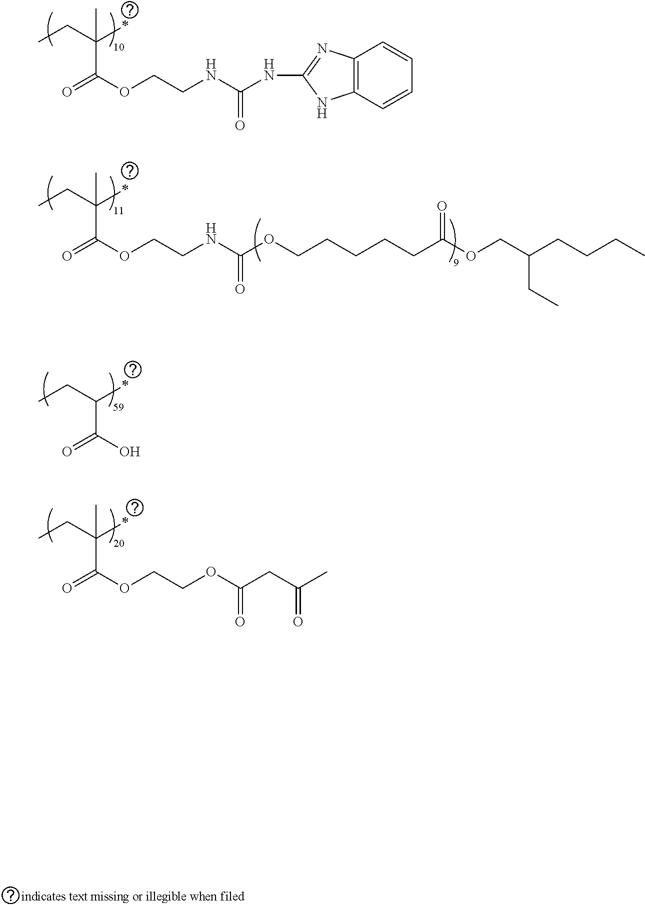

D4: resin having the following structure (the numerical value described together with the main chain indicates a molar ratio, and the numerical value described together with the side chain indicates the number of repeating units; Mw=7000)

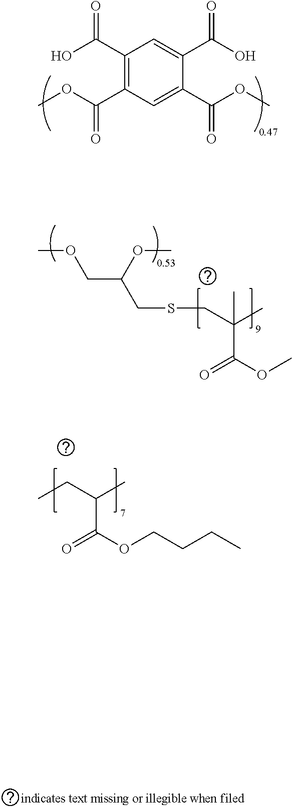

D5: resin having the following structure (the numerical value described together with the main chain indicates a molar ratio, and the numerical value described together with the side chain indicates the number of repeating units; Mw=16000)

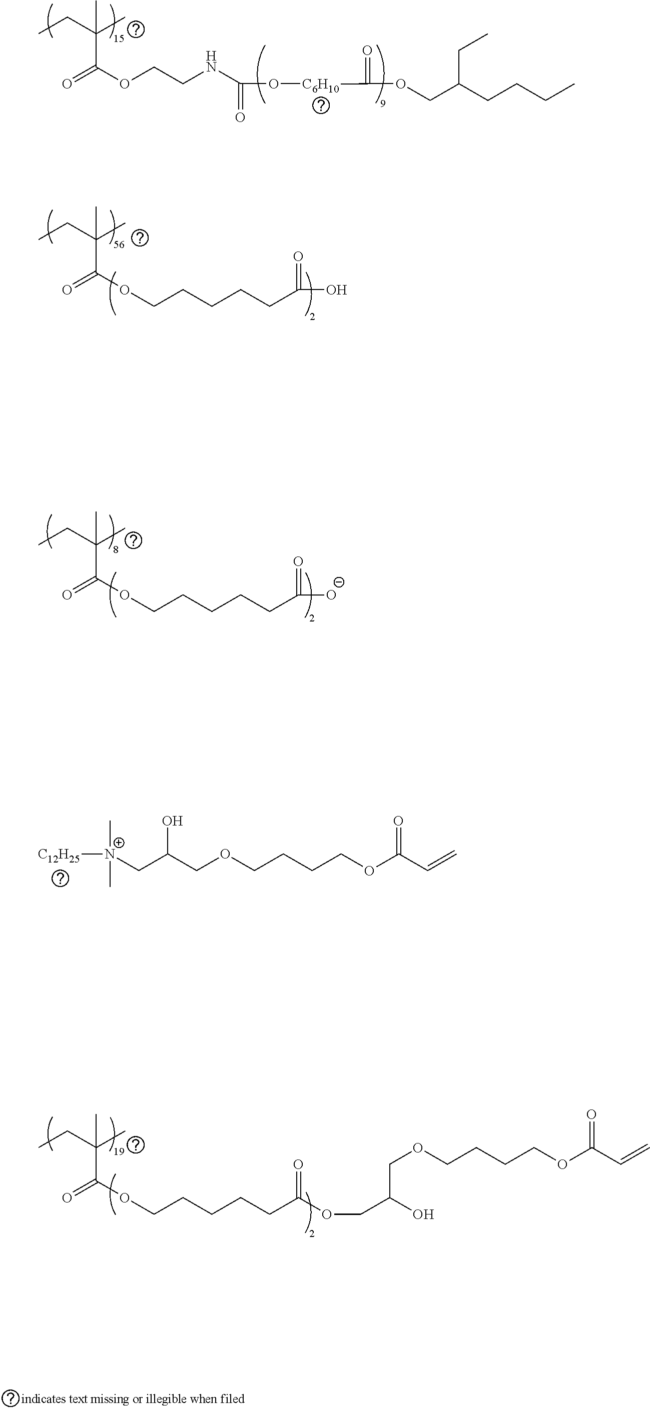

D6: resin having the following structure (the numerical value described together with the main chain indicates a molar ratio, and the numerical value described together with the side chain indicates the number of repeating units; Mw=10000)

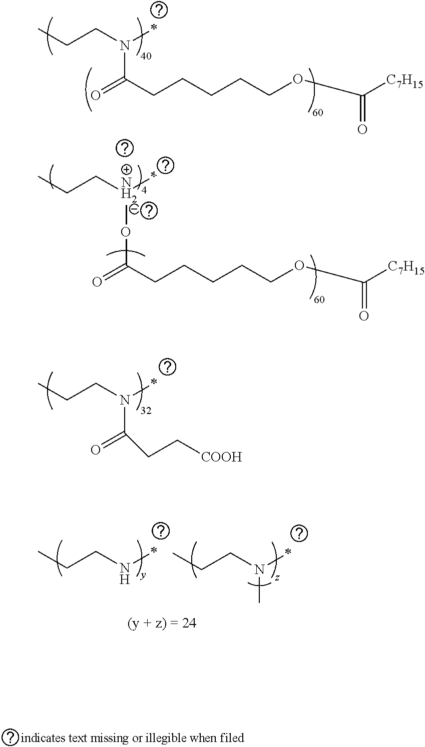

D7: acrylic block copolymer (EB-1) described in paragraph No. 0219 of JP6432077B

D9: DISPERBYK-142 (manufactured by BYK Chemie)

D10: resin having the following structure (block copolymer; the numerical value described together with the main chain indicates a molar ratio, Mw=6000)

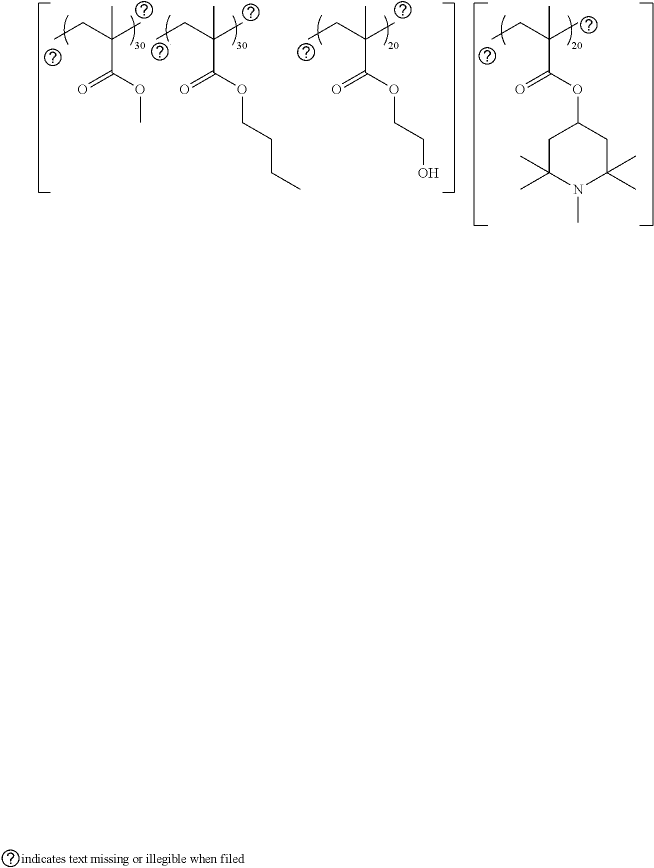

D11: resin having the following structure (the numerical value described together with the main chain indicates a molar ratio, and the numerical value described together with the side chain indicates the number of repeating units; Mw=7500)

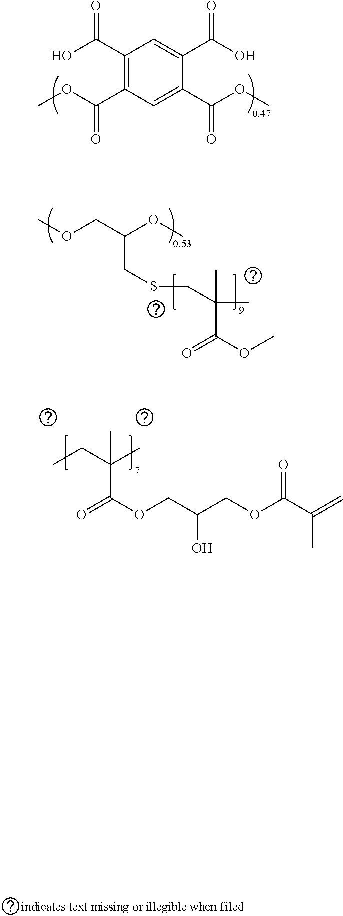

(Solvent)

S1: propylene glycol monomethyl ether acetate (PGMEA)

S2: cyclohexanone

S3: butyl acetate

S4: ethyl lactate

S5: propylene glycol monomethyl ether (PGME)

S6: cyclopentanone

(Polymerization Inhibitor)

H1: p-methoxyphenol

<Evaluation of Dispersion Liquid>

(Particle Size)

Using a particle size distribution meter (Nanotrac UPA-EX150, manufactured by Nikkiso Co., Ltd.), the average particle diameter (secondary particle diameter) of the pigment in the dispersion liquid immediately after production was measured by a dynamic light scattering method. It is preferable that the average particle diameter is smaller.

A: average particle diameter of the pigment was less than 100 nm.

B: average particle diameter of the pigment was 100 nm or more and less than 200 nm.

C: average particle diameter of the pigment was 200 nm or more.

(Initial Viscosity)

Using an E-type viscometer under the condition of a rotation speed of 1000 rpm (revolutions per minute), the viscosity (mPa·s) of the dispersion liquid obtained above at 25° C. was measured, and evaluated according to the following standard.

A: 1 mPa·s or more and 15 mPa·s or less

B: more than 15 mPa·s and 30 mPa·s or less

C: more than 30 mPa·s

TABLE 4

| | | Initial |
|---|---|---|
| | Particle size | viscosity |
| Dispersion liquid 1 | A | A |
| Dispersion liquid 2 | A | A |
| Dispersion liquid 3 | B | B |
| Dispersion liquid 4 | B | B |
| Dispersion liquid 5 | A | B |
| Dispersion liquid 6 | A | B |
| Dispersion liquid 7 | A | A |
| Dispersion liquid 8 | A | B |
| Dispersion liquid 9 | A | B |
| Dispersion liquid 10 | A | B |
| Dispersion liquid 11 | B | B |
| Dispersion liquid 12 | A | A |
| Dispersion liquid 13 | A | B |
| Dispersion liquid 14 | A | A |
| Dispersion liquid 15 | A | A |
| Dispersion liquid 16 | A | A |
| Dispersion liquid 17 | A | A |
| Dispersion liquid 18 | A | A |
| Dispersion liquid 19 | A | A |
| Dispersion liquid 20 | A | A |
| Dispersion liquid 21 | A | A |
| Dispersion liquid 22 | A | A |
| Dispersion liquid 23 | A | A |
| Dispersion liquid 24 | A | A |
| Dispersion liquid 25 | A | A |
| Dispersion liquid 26 | A | A |
| Dispersion liquid 27 | B | B |
| Dispersion liquid 28 | B | C |
| Dispersion liquid 29 | B | C |
| Dispersion liquid 30 | A | C |
| Dispersion liquid 31 | A | A |
| Dispersion liquid 32 | A | A |
| Dispersion liquid 33 | A | A |
| Dispersion liquid 34 | A | B |
| Dispersion liquid 35 | A | B |
| Dispersion liquid 36 | B | B |
| Dispersion liquid 37 | A | A |
| Dispersion liquid 38 | A | A |
| Dispersion liquid 39 | A | A |
| Dispersion liquid 40 | A | A |
| Dispersion liquid 41 | A | A |
| Dispersion liquid 42 | A | A |
| Dispersion liquid 43 | A | A |
| Dispersion liquid 44 | A | A |
| Dispersion liquid 45 | A | A |
| Dispersion liquid 46 | B | A |
| Dispersion liquid 47 | A | A |
| Dispersion liquid 48 | A | A |
| Dispersion liquid 49 | A | A |
| Dispersion liquid 50 | A | A |
| Dispersion liquid 51 | A | A |
| Dispersion liquid 52 | A | A |
| Dispersion liquid 53 | A | A |
| Dispersion liquid 54 | A | A |
| Dispersion liquid 55 | A | A |
| Dispersion liquid 56 | A | A |
| Dispersion liquid 57 | A | A |
| Dispersion liquid 58 | A | A |
| Dispersion liquid 59 | A | A |
| Dispersion liquid 60 | A | A |
| Dispersion liquid 61 | A | A |
| Dispersion liquid 62 | A | A |
| Dispersion liquid 63 | A | A |
| Dispersion liquid 64 | A | A |
| Dispersion liquid 65 | A | A |
| Dispersion liquid 66 | A | A |
| Dispersion liquid 67 | A | A |
| Dispersion liquid 68 | A | A |
| Dispersion liquid 69 | A | B |
| Dispersion liquid 70 | A | A |
| Dispersion liquid 71 | A | A |
| Dispersion liquid 72 | A | A |
| Dispersion liquid 73 | B | B |
| Dispersion liquid 74 | A | A |
| Comparative dispersion | C | C |
| liquid 1 | | |

<Preparation of Coloring Composition>

The following raw materials were mixed to prepare a coloring composition.

TABLE 5

| | Dispersion | | | | Polymerizable | | Photopolymerization | | | |
|---|---|---|---|---|---|---|---|---|---|---|
| | liquid | | Binder | | monomer | | initiator | | Surfactant | |
| | | Part | | Part | | Part | | Part | | Part |
| | | by | | by | | by | | by | | by |
| | Type | mass | Type | mass | Type | mass | Type | mass | Type | mass |
| Example 1 | Dispersion liquid 1 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 2 | Dispersion liquid 2 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 3 | Dispersion liquid 3 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 4 | Dispersion liquid 4 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 5 | Dispersion liquid 5 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 6 | Dispersion liquid 6 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 7 | Dispersion liquid 7 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 8 | Dispersion liquid 8 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 9 | Dispersion liquid 9 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 10 | Dispersion liquid 10 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 11 | Dispersion liquid 11 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 12 | Dispersion liquid 12 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 13 | Dispersion liquid 13 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 14 | Dispersion liquid 14 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 15 | Dispersion liquid 15 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 16 | Dispersion liquid 16 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 17 | Dispersion liquid 17 | 82.69 | D1 | 0.14 | M1 | 1.00 | F1 | 0.20 | W2 | 0.139 |
| | | | D3 | 0.23 | M4 | 0.60 | F3 | 0.50 | | |
| | Polymerization | | Ultraviolet | | | | Epoxy | | | |
| | inhibitor | | absorber | | Antioxidant | | compound | | Solvent | |
| | | Part | | Part | | Part | | Part | | Part |
| | | by | | by | | by | | by | | by |
| | Type | mass | Type | mass | Type | mass | Type | mass | Type | mass |
| Example 1 | H1 | 0.001 | UV1 | 0.3 | — | 0 | — | 0 | S1 | 9.8 |
| | | | | | | | | | S5 | 4.4 |
| Example 2 | H1 | 0.001 | UV1 | 0.3 | — | 0 | — | 0 | S1 | 9.8 |
| | | | | | | | | | S5 | 4.4 |
| Example 3 | H1 | 0.001 | UV1 | 0.3 | — | 0 | — | 0 | S1 | 9.8 |
| | | | | | | | | | S5 | 4.4 |
| Example 4 | H1 | 0.001 | UV1 | 0.3 | — | 0 | — | 0 | S1 | 9.8 |
| | | | | | | | | | S5 | 4.4 |
| Example 5 | H1 | 0.001 | UV1 | 0.3 | — | 0 | — | 0 | S1 | 9.8 |
| | | | | | | | | | S5 | 4.4 |
| Example 6 | H1 | 0.001 | UV1 | 0.3 | — | 0 | — | 0 | S1 | 9.8 |
| | | | | | | | | | S5 | 4.4 |
| Example 7 | H1 | 0.001 | UV1 | 0.3 | — | 0 | — | 0 | S1 | 9.8 |
| | | | | | | | | | S5 | 4.4 |
| Example 8 | H1 | 0.001 | UV1 | 0.3 | — | 0 | — | 0 | S1 | 9.8 |
| | | | | | | | | | S5 | 4.4 |
| Example 9 | H1 | 0.001 | UV1 | 0.3 | — | 0 | — | 0 | S1 | 9.8 |
| | | | | | | | | | S5 | 4.4 |
| Example 10 | H1 | 0.001 | UV1 | 0.3 | — | 0 | — | 0 | S1 | 9.8 |
| | | | | | | | | | S5 | 4.4 |
| Example 11 | H1 | 0.001 | UV1 | 0.3 | — | 0 | — | 0 | S1 | 9.8 |
| | | | | | | | | | S5 | 4.4 |
| Example 12 | H1 | 0.001 | UV1 | 0.3 | — | 0 | — | 0 | S1 | 9.8 |
| | | | | | | | | | S5 | 4.4 |
| Example 13 | H1 | 0.001 | UV1 | 0.3 | — | 0 | — | 0 | S1 | 9.8 |
| | | | | | | | | | S5 | 4.4 |
| Example 14 | H1 | 0.001 | UV1 | 0.3 | — | 0 | — | 0 | S1 | 9.8 |
| | | | | | | | | | S5 | 4.4 |
| Example 15 | H1 | 0.001 | UV1 | 0.3 | — | 0 | — | 0 | S1 | 9.8 |
| | | | | | | | | | S5 | 4.4 |
| Example 16 | H1 | 0.001 | UV1 | 0.3 | — | 0 | — | 0 | S1 | 9.8 |
| | | | | | | | | | S5 | 4.4 |
| Example 17 | H1 | 0.001 | UV1 | 0.3 | — | 0 | — | 0 | S1 | 9.8 |
| | | | | | | | | | S5 | 4.4 |

TABLE 6

| | Dispersion | | | | Polymerizable | | Photopolymerization | | | |
|---|---|---|---|---|---|---|---|---|---|---|
| | liquid | | Binder | | monomer | | initiator | | Surfactant | |
| | | Part | | Part | | Part | | Part | | Part |
| | | by | | by | | by | | by | | by |
| | Type | mass | Type | mass | Type | mass | Type | mass | Type | mass |
| Example 18 | Dispersion liquid 18 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 19 | Dispersion liquid 19 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 20 | Dispersion liquid 20 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 21 | Dispersion liquid 21 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 22 | Dispersion liquid 22 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 23 | Dispersion liquid 23 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 24 | Dispersion liquid 24 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 25 | Dispersion liquid 25 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 26 | Dispersion liquid 26 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 27 | Dispersion liquid 27 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 28 | Dispersion liquid 28 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 29 | Dispersion liquid 29 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 30 | Dispersion liquid 30 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 31 | Dispersion liquid 31 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 32 | Dispersion liquid 32 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 33 | Dispersion liquid 33 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 34 | Dispersion liquid 34 | 82.69 | D1 | 0.14 | M1 | 1.00 | F1 | 0.20 | W2 | 0.139 |
| | | | D3 | 0.23 | M4 | 0.60 | F3 | 0.50 | | |
| | Polymerization | | Ultraviolet | | | | Epoxy | | | |
| | inhibitor | | absorber | | Antioxidant | | compound | | Solvent | |
| | | Part | | Part | | Part | | Part | | Part |
| | | by | | by | | by | | by | | by |
| | Type | mass | Type | mass | Type | mass | Type | mass | Type | mass |
| Example 18 | H1 | 0.001 | UV1 | 0.3 | — | 0 | — | 0 | S1 | 9.8 |
| | | | | | | | | | S5 | 4.4 |
| Example 19 | H1 | 0.001 | UV1 | 0.3 | — | 0 | — | 0 | S1 | 9.8 |
| | | | | | | | | | S5 | 4.4 |
| Example 20 | H1 | 0.001 | UV1 | 0.3 | — | 0 | — | 0 | S1 | 9.8 |
| | | | | | | | | | S5 | 4.4 |
| Example 21 | H1 | 0.001 | UV1 | 0.3 | — | 0 | — | 0 | S1 | 9.8 |
| | | | | | | | | | S5 | 4.4 |
| Example 22 | H1 | 0.001 | UV1 | 0.3 | — | 0 | — | 0 | S1 | 9.8 |
| | | | | | | | | | S5 | 4.4 |
| Example 23 | H1 | 0.001 | UV1 | 0.3 | — | 0 | — | 0 | S1 | 9.8 |
| | | | | | | | | | S5 | 4.4 |
| Example 24 | H1 | 0.001 | UV1 | 0.3 | — | 0 | — | 0 | S1 | 9.8 |
| | | | | | | | | | S5 | 4.4 |
| Example 25 | H1 | 0.001 | UV1 | 0.3 | — | 0 | — | 0 | S1 | 9.8 |
| | | | | | | | | | S5 | 4.4 |
| Example 26 | H1 | 0.001 | UV1 | 0.3 | — | 0 | — | 0 | S1 | 9.8 |
| | | | | | | | | | S5 | 4.4 |
| Example 27 | H1 | 0.001 | UV1 | 0.3 | — | 0 | — | 0 | S1 | 9.8 |
| | | | | | | | | | S5 | 4.4 |
| Example 28 | H1 | 0.001 | UV1 | 0.3 | — | 0 | — | 0 | S1 | 9.8 |
| | | | | | | | | | S5 | 4.4 |
| Example 29 | H1 | 0.001 | UV1 | 0.3 | — | 0 | — | 0 | S1 | 9.8 |
| | | | | | | | | | S5 | 4.4 |
| Example 30 | H1 | 0.001 | UV1 | 0.3 | — | 0 | — | 0 | S1 | 9.8 |
| | | | | | | | | | S5 | 4.4 |
| Example 31 | H1 | 0.001 | UV1 | 0.3 | — | 0 | — | 0 | S1 | 9.8 |
| | | | | | | | | | S5 | 4.4 |
| Example 32 | H1 | 0.001 | UV1 | 0.3 | — | 0 | — | 0 | S1 | 9.8 |
| | | | | | | | | | S5 | 4.4 |
| Example 33 | H1 | 0.001 | UV1 | 0.3 | — | 0 | — | 0 | S1 | 9.8 |
| | | | | | | | | | S5 | 4.4 |
| Example 34 | H1 | 0.001 | UV1 | 0.3 | — | 0 | — | 0 | S1 | 9.8 |
| | | | | | | | | | S5 | 4.4 |

TABLE 7

| | Dispersion | | | | Polymerizable | | Photopolymerization | | | |
|---|---|---|---|---|---|---|---|---|---|---|
| | liquid | | Binder | | monomer | | initiator | | Surfactant | |
| | | Part | | Part | | Part | | Part | | Part |
| | | by | | by | | by | | by | | by |
| | Type | mass | Type | mass | Type | mass | Type | mass | Type | mass |
| Example 35 | Dispersion liquid 35 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 36 | Dispersion liquid 36 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 37 | Dispersion liquid 37 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 38 | Dispersion liquid 38 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 39 | Dispersion liquid 39 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 40 | Dispersion liquid 40 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 41 | Dispersion liquid 41 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 42 | Dispersion liquid 42 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 43 | Dispersion liquid 43 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 44 | Dispersion liquid 44 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 45 | Dispersion liquid 45 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 46 | Dispersion liquid 46 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 47 | Dispersion liquid 47 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 48 | Dispersion liquid 48 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 49 | Dispersion liquid 49 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 50 | Dispersion liquid 50 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 51 | Dispersion liquid 51 | 82.69 | D1 | 0.14 | M1 | 1.00 | F1 | 0.20 | W2 | 0.139 |
| | | | D3 | 0.23 | M4 | 0.60 | F3 | 0.50 | | |
| | Polymerization | | Ultraviolet | | | | Epoxy | | | |
| | inhibitor | | absorber | | Antioxidant | | compound | | Solvent | |
| | | Part | | Part | | Part | | Part | | Part |
| | | by | | by | | by | | by | | by |
| | Type | mass | Type | mass | Type | mass | Type | mass | Type | mass |
| Example 35 | H1 | 0.001 | UV1 | 0.3 | — | 0 | — | 0 | S1 | 9.8 |
| | | | | | | | | | S5 | 4.4 |
| Example 36 | H1 | 0.001 | UV1 | 0.3 | — | 0 | — | 0 | S1 | 9.8 |
| | | | | | | | | | S5 | 4.4 |
| Example 37 | H1 | 0.001 | UV1 | 0.3 | — | 0 | — | 0 | S1 | 9.8 |
| | | | | | | | | | S5 | 4.4 |
| Example 38 | H1 | 0.001 | UV1 | 0.3 | — | 0 | — | 0 | S1 | 9.8 |
| | | | | | | | | | S5 | 4.4 |
| Example 39 | H1 | 0.001 | UV1 | 0.3 | — | 0 | — | 0 | S1 | 9.8 |
| | | | | | | | | | S5 | 4.4 |
| Example 40 | H1 | 0.001 | UV1 | 0.3 | — | 0 | — | 0 | S1 | 9.8 |
| | | | | | | | | | S5 | 4.4 |
| Example 41 | H1 | 0.001 | UV1 | 0.3 | — | 0 | — | 0 | S1 | 9.8 |
| | | | | | | | | | S5 | 4.4 |
| Example 42 | H1 | 0.001 | UV1 | 0.3 | — | 0 | — | 0 | S1 | 9.8 |
| | | | | | | | | | S5 | 4.4 |
| Example 43 | H1 | 0.001 | UV1 | 0.3 | — | 0 | — | 0 | S1 | 9.8 |
| | | | | | | | | | S5 | 4.4 |
| Example 44 | H1 | 0.001 | UV1 | 0.3 | — | 0 | — | 0 | S1 | 9.8 |
| | | | | | | | | | S5 | 4.4 |
| Example 45 | H1 | 0.001 | UV1 | 0.3 | — | 0 | — | 0 | S1 | 9.8 |
| | | | | | | | | | S5 | 4.4 |
| Example 46 | H1 | 0.001 | UV1 | 0.3 | — | 0 | — | 0 | S1 | 9.8 |
| | | | | | | | | | S5 | 4.4 |
| Example 47 | H1 | 0.001 | UV1 | 0.3 | — | 0 | — | 0 | S1 | 9.8 |
| | | | | | | | | | S5 | 4.4 |
| Example 48 | H1 | 0.001 | UV1 | 0.3 | — | 0 | — | 0 | S1 | 9.8 |
| | | | | | | | | | S5 | 4.4 |
| Example 49 | H1 | 0.001 | UV1 | 0.3 | — | 0 | — | 0 | S1 | 9.8 |
| | | | | | | | | | S5 | 4.4 |
| Example 50 | H1 | 0.001 | UV1 | 0.3 | — | 0 | — | 0 | S1 | 9.8 |
| | | | | | | | | | S5 | 4.4 |
| Example 51 | H1 | 0.001 | UV1 | 0.3 | — | 0 | — | 0 | S1 | 9.8 |
| | | | | | | | | | S5 | 4.4 |

TABLE 8

| | Dispersion | | | | Polymerizable | | Photopolymerization | | | |
|---|---|---|---|---|---|---|---|---|---|---|
| | liquid | | Binder | | monomer | | initiator | | Surfactant | |
| | | Part | | Part | | Part | | Part | | Part |
| | | by | | by | | by | | by | | by |
| | Type | mass | Type | mass | Type | mass | Type | mass | Type | mass |
| Example 52 | Dispersion liquid 52 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 53 | Dispersion liquid 53 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 54 | Dispersion liquid 54 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 55 | Dispersion liquid 55 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 56 | Dispersion liquid 56 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 57 | Dispersion liquid 57 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 58 | Dispersion liquid 58 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 59 | Dispersion liquid 59 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 60 | Dispersion liquid 60 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 61 | Dispersion liquid 61 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 62 | Dispersion liquid 62 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 63 | Dispersion liquid 63 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 64 | Dispersion liquid 64 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 65 | Dispersion liquid 65 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 66 | Dispersion liquid 66 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 67 | Dispersion liquid 67 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 68 | Dispersion liquid 68 | 82.69 | D1 | 0.14 | M1 | 1.00 | F1 | 0.20 | W2 | 0.139 |
| | | | D3 | 0.23 | M4 | 0.60 | F3 | 0.50 | | |
| | Polymerization | | Ultraviolet | | | | Epoxy | | | |
| | inhibitor | | absorber | | Antioxidant | | compound | | Solvent | |
| | | Part | | Part | | Part | | Part | | Part |
| | | by | | by | | by | | by | | by |
| | Type | mass | Type | mass | Type | mass | Type | mass | Type | mass |
| Example 52 | H1 | 0.001 | UV1 | 0.3 | — | 0 | — | 0 | S1 | 9.8 |
| | | | | | | | | | S5 | 4.4 |
| Example 53 | H1 | 0.001 | UV1 | 0.3 | — | 0 | — | 0 | S1 | 9.8 |
| | | | | | | | | | S5 | 4.4 |
| Example 54 | H1 | 0.001 | UV1 | 0.3 | — | 0 | — | 0 | S1 | 9.8 |
| | | | | | | | | | S5 | 4.4 |
| Example 55 | H1 | 0.001 | UV1 | 0.3 | — | 0 | — | 0 | S1 | 9.8 |
| | | | | | | | | | S5 | 4.4 |
| Example 56 | H1 | 0.001 | UV1 | 0.3 | — | 0 | — | 0 | S1 | 9.8 |
| | | | | | | | | | S5 | 4.4 |
| Example 57 | H1 | 0.001 | UV1 | 0.3 | — | 0 | — | 0 | S1 | 9.8 |
| | | | | | | | | | S5 | 4.4 |
| Example 58 | H1 | 0.001 | UV1 | 0.3 | — | 0 | — | 0 | S1 | 9.8 |
| | | | | | | | | | S5 | 4.4 |
| Example 59 | H1 | 0.001 | UV1 | 0.3 | — | 0 | — | 0 | S1 | 9.8 |
| | | | | | | | | | S5 | 4.4 |
| Example 60 | H1 | 0.001 | UV1 | 0.3 | — | 0 | — | 0 | S1 | 9.8 |
| | | | | | | | | | S5 | 4.4 |
| Example 61 | H1 | 0.001 | UV1 | 0.3 | — | 0 | — | 0 | S1 | 9.8 |
| | | | | | | | | | S5 | 4.4 |
| Example 62 | H1 | 0.001 | UV1 | 0.3 | — | 0 | — | 0 | S1 | 9.8 |
| | | | | | | | | | S5 | 4.4 |
| Example 63 | H1 | 0.001 | UV1 | 0.3 | — | 0 | — | 0 | S1 | 9.8 |
| | | | | | | | | | S5 | 4.4 |
| Example 64 | H1 | 0.001 | UV1 | 0.3 | — | 0 | — | 0 | S1 | 9.8 |
| | | | | | | | | | S5 | 4.4 |
| Example 65 | H1 | 0.001 | UV1 | 0.3 | — | 0 | — | 0 | S1 | 9.8 |
| | | | | | | | | | S5 | 4.4 |
| Example 66 | H1 | 0.001 | UV1 | 0.3 | — | 0 | — | 0 | S1 | 9.8 |
| | | | | | | | | | S5 | 4.4 |
| Example 67 | H1 | 0.001 | UV1 | 0.3 | — | 0 | — | 0 | S1 | 9.8 |
| | | | | | | | | | S5 | 4.4 |
| Example 68 | H1 | 0.001 | UV1 | 0.3 | — | 0 | — | 0 | S1 | 9.8 |
| | | | | | | | | | S5 | 4.4 |

TABLE 9

| | Dispersion | | | | Polymerizable | | Photopolymerization | | | |
|---|---|---|---|---|---|---|---|---|---|---|
| | liquid | | Binder | | monomer | | initiator | | Surfactant | |
| | | Part | | Part | | Part | | Part | | Part |
| | | by | | by | | by | | by | | by |
| | Type | mass | Type | mass | Type | mass | Type | mass | Type | mass |
| Example 69 | Dispersion liquid 69 | 86.00 | D1 | 0.25 | M1 | 1.00 | F1 | 0.20 | W2 | 0.139 |
| | | | D3 | 0.25 | M4 | 0.60 | F3 | 0.50 | | |
| Example 70 | Dispersion liquid 70 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 71 | Dispersion liquid 71 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 72 | Dispersion liquid 72 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 73 | Dispersion liquid 73 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 74 | Dispersion liquid 74 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 75 | Dispersion liquid 1 | 82.69 | D2 | 0.37 | M1 | 1.00 | F1 | 0.20 | W2 | 0.139 |
| | | | | | M4 | 0.60 | F3 | 0.50 | | |
| Example 76 | Dispersion liquid 1 | 82.69 | D8 | 0.37 | M1 | 1.00 | F1 | 0.20 | W2 | 0.139 |
| | | | | | M4 | 0.60 | F3 | 0.50 | | |
| Example 77 | Dispersion liquid 1 | 82.69 | D1 | 0.14 | M2 | 1.6 | F1 | 0.20 | W2 | 0.139 |
| | | | D3 | 0.23 | | | F3 | 0.50 | | |
| Example 78 | Dispersion liquid 1 | 82.69 | D1 | 0.14 | M3 | 1.6 | F1 | 0.20 | W2 | 0.139 |
| | | | D3 | 0.23 | | | F3 | 0.50 | | |
| Example 79 | Dispersion liquid 1 | 82.69 | D1 | 0.14 | M5 | 1.6 | F1 | 0.20 | W2 | 0.139 |
| | | | D3 | 0.23 | | | F3 | 0.50 | | |
| Example 80 | Dispersion liquid 1 | 82.69 | D1 | 0.14 | M6 | 1.6 | F1 | 0.20 | W2 | 0.139 |
| | | | D3 | 0.23 | | | F3 | 0.50 | | |
| Example 81 | Dispersion liquid 1 | 82.69 | D1 | 0.14 | M1 | 1.00 | F2 | 0.7 | W2 | 0.139 |
| | | | D3 | 0.23 | M4 | 0.60 | | | | |
| Example 82 | Dispersion liquid 1 | 82.69 | D1 | 0.14 | M1 | 1.00 | F4 | 0.7 | W2 | 0.139 |
| | | | D3 | 0.23 | M4 | 0.60 | | | | |
| Example 83 | Dispersion liquid 1 | 82.69 | D1 | 0.14 | M1 | 1.00 | F5 | 0.7 | W2 | 0.139 |
| | | | D3 | 0.23 | M4 | 0.60 | | | | |
| Example 84 | Dispersion liquid 1 | 82.69 | D1 | 0.14 | M1 | 1.00 | F6 | 0.7 | W2 | 0.139 |
| | | | D3 | 0.23 | M4 | 0.60 | | | | |
| Example 85 | Dispersion liquid 1 | 82.69 | D1 | 0.14 | M1 | 1.00 | F1 | 0.20 | W2 | 0.139 |
| | | | D3 | 0.23 | M4 | 0.60 | F4 | 0.50 | | |
| | Polymerization | | Ultraviolet | | | | Epoxy | | | |
| | inhibitor | | absorber | | Antioxidant | | compound | | Solvent | |
| | | Part | | Part | | Part | | Part | | Part |
| | | by | | by | | by | | by | | by |
| | Type | mass | Type | mass | Type | mass | Type | mass | Type | mass |
| Example 69 | H1 | 0.001 | UV1 | 0.3 | — | 0 | — | 0 | S1 | 7.76 |
| | | | | | | | | | S5 | 3.00 |
| Example 70 | H1 | 0.001 | UV1 | 0.3 | — | 0 | — | 0 | S1 | 9.8 |
| | | | | | | | | | S5 | 4.4 |
| Example 71 | H1 | 0.001 | UV1 | 0.3 | — | 0 | — | 0 | S1 | 9.8 |
| | | | | | | | | | S5 | 4.4 |
| Example 72 | H1 | 0.001 | UV1 | 0.3 | — | 0 | — | 0 | S1 | 9.8 |
| | | | | | | | | | S5 | 4.4 |
| Example 73 | H1 | 0.001 | UV1 | 0.3 | — | 0 | — | 0 | S1 | 9.8 |
| | | | | | | | | | S5 | 4.4 |
| Example 74 | H1 | 0.001 | UV1 | 0.3 | — | 0 | — | 0 | S1 | 9.8 |
| | | | | | | | | | S5 | 4.4 |
| Example 75 | H1 | 0.001 | UV1 | 0.3 | — | 0 | — | 0 | S6 | 14.2 |
| Example 76 | H1 | 0.001 | UV1 | 0.3 | — | 0 | — | 0 | S1 | 9.8 |
| | | | | | | | | | S5 | 4.4 |
| Example 77 | H1 | 0.001 | UV1 | 0.3 | — | 0 | — | 0 | S1 | 14.2 |
| Example 78 | H1 | 0.001 | UV1 | 0.3 | — | 0 | — | 0 | S3 | 14.2 |
| Example 79 | H1 | 0.001 | UV1 | 0.3 | — | 0 | — | 0 | S1 | 9.8 |
| | | | | | | | | | S5 | 4.4 |
| Example 80 | H1 | 0.001 | UV1 | 0.3 | — | 0 | — | 0 | S1 | 9.8 |
| | | | | | | | | | S5 | 4.4 |
| Example 81 | H1 | 0.001 | UV1 | 0.3 | — | 0 | — | 0 | S2 | 14.2 |
| Example 82 | H1 | 0.001 | UV1 | 0.3 | — | 0 | — | 0 | S4 | 14.2 |
| Example 83 | H1 | 0.001 | UV1 | 0.3 | — | 0 | — | 0 | S1 | 9.8 |
| | | | | | | | | | S5 | 4.4 |
| Example 84 | H1 | 0.001 | UV1 | 0.3 | — | 0 | — | 0 | S1 | 9.8 |
| | | | | | | | | | S5 | 4.4 |
| Example 85 | H1 | 0.001 | UV1 | 0.3 | — | 0 | — | 0 | S1 | 9.8 |
| | | | | | | | | | S5 | 4.4 |

TABLE 10

| | Dispersion | | | | Polymerizable | | Photopolymerization | | | |
|---|---|---|---|---|---|---|---|---|---|---|
| | liquid | | Binder | | monomer | | initiator | | Surfactant | |
| | | Part | | Part | | Part | | Part | | Part |
| | | by | | by | | by | | by | | by |
| | Type | mass | Type | mass | Type | mass | Type | mass | Type | mass |
| Example 86 | Dispersion liquid 1 | 82.69 | D1 | 0.14 | M1 | 1.00 | F1 | 0.20 | W1 | 0.139 |
| | | | D3 | 0.23 | M4 | 0.60 | F3 | 0.50 | | |
| Example 87 | Dispersion liquid 1 | 82.69 | D1 | 0.14 | M1 | 1.00 | F1 | 0.20 | W1 | 0.05 |
| | | | D3 | 0.23 | M4 | 0.60 | F3 | 0.50 | W2 | 0.089 |
| Example 88 | Dispersion liquid 1 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 89 | Dispersion liquid 1 | 82.69 | D1 | 0.14 | M1 | 1.00 | F1 | 0.20 | W2 | 0.139 |
| | | | D3 | 0.23 | M4 | 0.60 | F3 | 0.50 | | |
| Example 90 | Dispersion liquid 1 | 82.69 | D1 | 0.14 | M1 | 1.00 | F1 | 0.20 | W2 | 0.137 |
| | | | D3 | 0.23 | M4 | 0.60 | F3 | 0.50 | | |
| Example 91 | Dispersion liquid 1 | 82.69 | D1 | 0.14 | M1 | 1.00 | F1 | 0.20 | W2 | 0.137 |
| | | | D3 | 0.23 | M4 | 0.60 | F3 | 0.50 | | |
| Example 92 | Dispersion liquid 1 | 42.69 | D1 | 0.14 | M1 | 1.00 | F1 | 0.20 | W2 | 0.139 |
| 92 | Dispersion liquid 23 | 40.00 | D3 | 0.23 | M4 | 0.60 | F3 | 0.50 | | |
| Example 93 | Dispersion liquid 1 | 66.00 | D1 | 5.37 | M1 | 6.60 | F1 | 0.70 | W1 | 0.14 |
| | | | | | | | F3 | | | |
| Example 94 | Dispersion liquid 1 | 40.00 | D1 | 1.37 | M1 | 2.00 | F1 | 0.70 | W1 | 0.14 |
| | | | | | | | F3 | | | |
| Comparative | Comparative dispersion | 82.69 | D1 | 0.14 | M1 | 1.00 | F1 | 0.20 | W2 | 0.139 |
| Example 1 | liquid 62 | | D3 | 0.23 | M4 | 0.60 | F3 | 0.50 | | |
| | Polymerization | | Ultraviolet | | | | Epoxy | | | |
| | inhibitor | | absorber | | Antioxidant | | compound | | Solvent | |
| | | Part | | Part | | Part | | Part | | Part |
| | | by | | by | | by | | by | | by |
| | Type | mass | Type | mass | Type | mass | Type | mass | Type | mass |
| Example 86 | H1 | 0.001 | UV1 | 0.3 | — | 0 | — | 0 | S6 | 14.2 |
| Example 87 | H1 | 0.001 | UV1 | 0.3 | — | 0 | — | 0 | S1 | 9.8 |
| | | | | | | | | | S5 | 4.4 |
| Example 88 | H1 | 0.001 | UV2 | 0.3 | — | 0 | — | 0 | S1 | 9.8 |
| | | | | | | | | | S5 | 4.4 |
| Example 89 | H1 | 0.001 | — | 0 | — | 0 | — | 0 | S1 | 9.8 |
| | | | | | | | | | S5 | 4.4 |
| Example 90 | H1 | 0.001 | UV1 | 0.3 | I1 | 0.002 | — | 0 | S1 | 9.8 |
| | | | | | | | | | S5 | 4.4 |
| Example 91 | H1 | 0.001 | UV1 | 0.3 | — | 0 | G1 | 0.002 | S1 | 9.8 |
| | | | | | | | | | S5 | 4.4 |
| Example 92 | H1 | 0.001 | UV1 | 0.3 | — | 0 | — | 0 | S1 | 9.8 |
| | | | | | | | | | S5 | 4.4 |
| Example 93 | H1 | 0.00 | UV1 | 0.30 | — | 0.00 | — | 0.00 | S1 | 20.89 |
| Example 94 | H1 | 0.00 | UV1 | 0.30 | — | 0.00 | — | 0.00 | S1 | 55.49 |
| Comparative | H1 | 0.001 | UV1 | 0.3 | — | 0 | — | 0 | S1 | 9.8 |
| Example 1 | | | | | | | | | S5 | 4.4 |

Details of the materials indicated by the above abbreviations are as follows.

(Dispersion liquid)

Dispersion liquids 1 to 74: dispersion liquids 1 to 74 described above

Comparative dispersion liquid 1: comparative dispersion liquid 1 described above

(Binder)

D1, D3: resins described in the dispersants D1 and D3 described above

D2: resin having the following structure (Mw=11000; the numerical value described together with the main chain indicates a molar ratio)

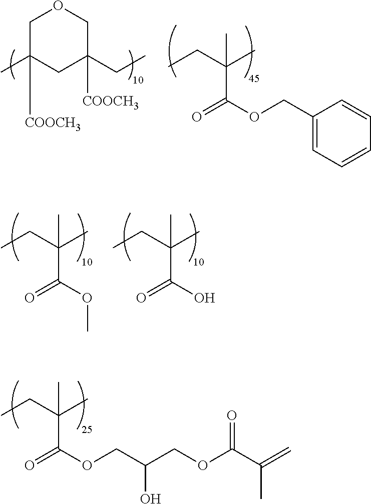

D8: resin having the following structure (Mw=11000; the numerical value described together with the main chain indicates a molar ratio)

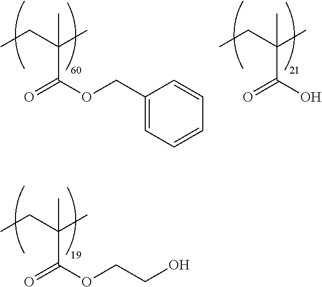

(Polymerizable Monomer)

M1: mixture of compounds having the following structures (mixture in which a molar ratio of a compound on the left (hexafunctional (meth)acrylate compound) and a compound on the right (pentafuctional (meth)acrylate compound) was 7:3)

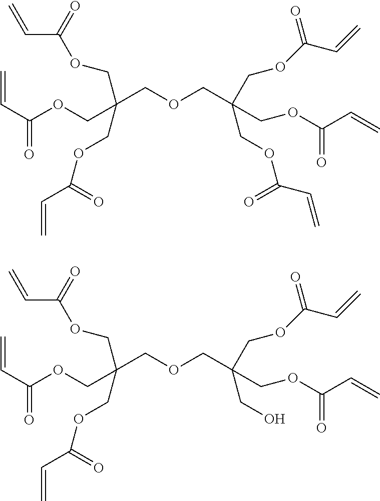 [SMILES: C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

M2: compound having the following structure

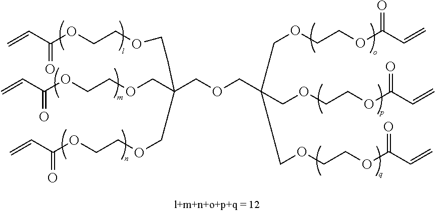

M3: compound having the following structure

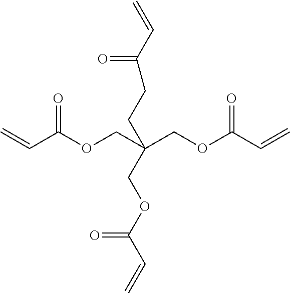 [SMILES: C=CC(=O)CCC(COC(=O)C=C)(COC(=O)C=C)COC(=O)C=C]

M4: succinic acid-modified dipentaerythritol hexaacrylate

M5: compound having the following structure

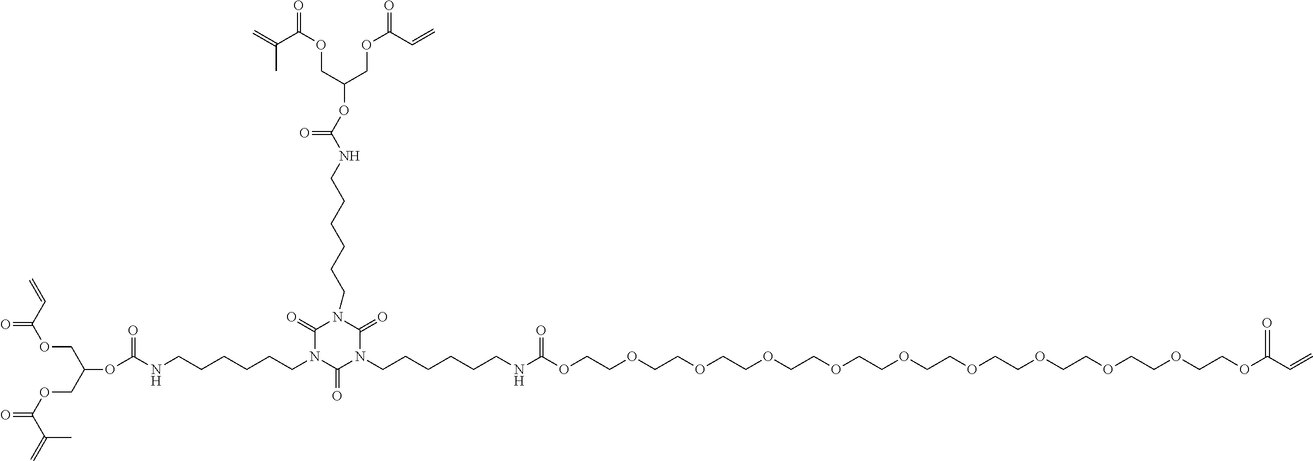 [SMILES: C=CC(=O)OCCOCCOCCOCCOCCOCCOCCOCCOCCOCCOC(=O)NCCCCCCn1c(=O)n(CCCCCCNC(=O)OC(COC(=O)C=C)COC(=O)C(=C)C)c(=O)n(CCCCCCNC(=O)OC(COC(=O)C=C)COC(=O)C(=C)C)c1=O]

M6: compound having the following structure

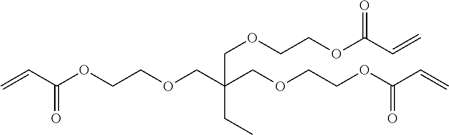 [SMILES: C=CC(=O)OCCOCC(CC)(COCCOC(=O)C=C)COCCOC(=O)C=C]

(Photopolymerization Initiator)

F1 to F6: compounds having the following structures

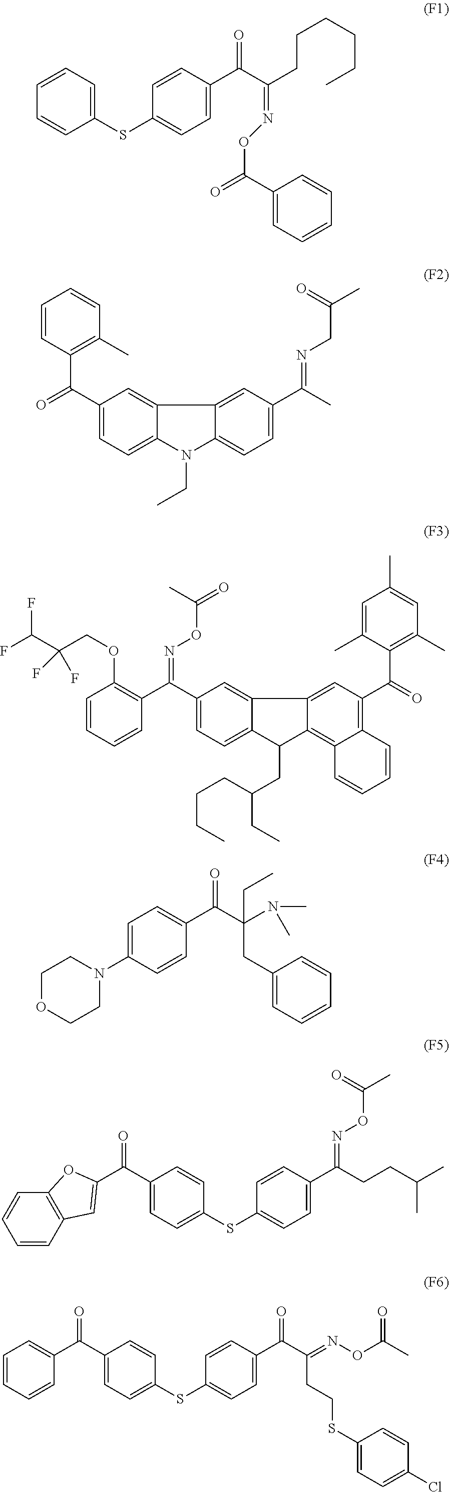

(Surfactant)

W1: compound having the following structure (Mw=14000; the numerical value “%” representing the proportion of the repeating unit is mol %; fluorine-based surfactant)

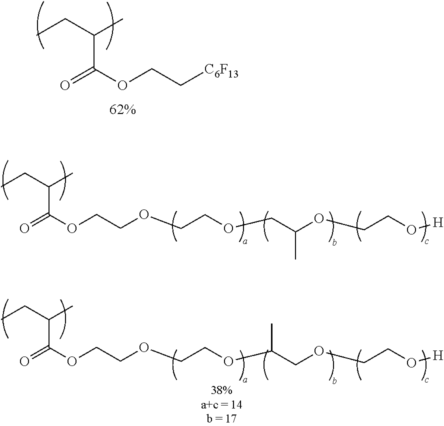

W2: compound having the following structure (Mw=3000, silicone-based surfactant)

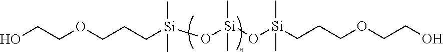

(Polymerization Inhibitor)

H1: p-methoxyphenol

(Ultraviolet Absorber)

UV1, UV2: compounds having the following structures

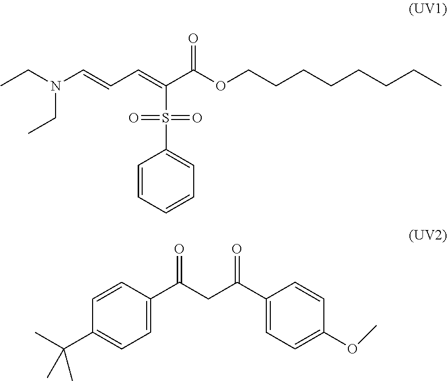

(Antioxidant)

I1: compound having the following structure

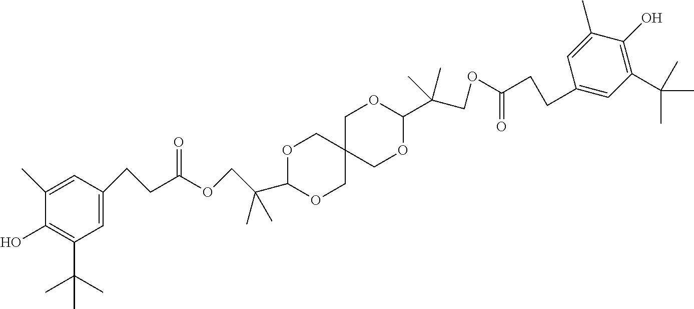 [SMILES: Cc1cc(CCC(=O)OCC(C)(C)C2OCC3(CO2)COC(C(C)(C)COC(=O)CCc2cc(C)c(O)c(C(C)(C)C)c2)OC3)cc(C(C)(C)C)c1O]

(Epoxy Compound)

G1: EHPE 3150 (manufactured by Daicel Corporation)

(Solvent)

S1: propylene glycol monomethyl ether acetate (PGMEA)

S2: cyclohexanone

S3: butyl acetate

S4: ethyl lactate

S5: propylene glycol monomethyl ether (PGME)

S6: cyclopentanone

<Evaluation of Defects>

Each coloring composition was applied to an 8-inch (20.32 cm) silicon wafer by CLEAN TRACK ACT-8 (manufactured by Tokyo Electron Limited.), pre-baked at 100° C. for 120 seconds, and post-baked at 200° C. for 30 minutes to form a film having a film thickness of 0.8 μm. The silicon wafer on which the film had been formed was inspected by a defect inspection apparatus ComPLUS3 manufactured by Applied Materials, Inc. to detect a defective portion (aggregates), and the number of defects having a size of 1 μm or more in 2462 cm² was extracted.

A: 20 or less

B: more than 20 and 50 or less

C: more than 50 and 100 or less

D: more than 100

<Evaluation of Film Thickness Reduction>

Each coloring composition was applied to a silicon wafer using a spin coater such that the film thickness after pre-baking was 0.7 μm, and a heating treatment was performed for 120 seconds using a hot plate at 100° C. Next, using an i-ray stepper exposure device FPA-3000 i5+ (manufactured by Canon Inc.), the silicon wafer was irradiated with light having a wavelength of 365 nm to perform exposure thereon with an exposure amount of 500 mJ/cm². Next, a heating treatment (post-baking) was performed for 300 seconds using a hot plate at 220° C., thereby forming a film. The obtained film was subjected to a moisture resistance test for 250 hours under conditions of a temperature of 130° C. and a humidity of 85% using a moisture resistance tester (HASTEST MODEL304R8, manufactured by HIRAYAMA), and then the film thickness after the moisture resistance test was measured.

In a case where [Film thickness after moisture resistance test]/[Film thickness before moisture resistance test]=X, the film thickness reduction was evaluated according to the following standard.

A: X≥0.95

B: 0.9≤X<0.95

C: 0.8≤X<0.9

D: 0.7≤X<0.8

E:X<0.7

<Evaluation of Spectral Characteristics>

Each coloring composition was applied to a glass substrate by spin coating so that a thickness of a film after post-baking was 0.6 μm. The coloring composition was dried by a hot plate at 100° C. for 120 seconds. Next, a heat treatment (post-baking) was performed for 300 seconds using a hot plate at 200° C. to form a film. Using an ultraviolet-visible-near infrared spectrophotometer U-4100 (manufactured by Hitachi High-Tech Corporation) (ref. glass substrate), the light transmittance of the glass substrate on which the film formed was measured in a wavelength range of 300 to 1000 nm. The spectral characteristics was evaluated using a transmittance ratio T calculated from the following expression. As the value of the transmittance ratio T is lower, the spectroscopy is excellent.

T=(Tmin/Tmax)×100(%)

Tmax: maximum transmittance at wavelength of 500 to 600 nm

Tmin: minimum transmittance at wavelength of 620 to 730 nm

[Evaluation Standard]

A: T<10

B: 10≤T<20

C: 20≤T<30

D: 30≤T

TABLE 11

| | Evaluation result | | |
|---|---|---|---|
| | | | Film |
| | | Spectral | thickness |
| | Defect | characteristics | reduction |
| Example 1 | A | A | A |
| Example 2 | A | A | A |
| Example 3 | B | C | A |
| Example 4 | B | C | A |
| Example 5 | A | B | B |
| Example 6 | A | B | B |
| Example 7 | A | A | A |
| Example 8 | A | B | B |
| Example 9 | A | B | B |
| Example 10 | A | B | B |
| Example 11 | B | C | B |
| Example 12 | A | A | A |
| Example 13 | A | B | B |
| Example 14 | A | A | A |
| Example 15 | A | A | A |
| Example 16 | A | A | A |
| Example 17 | A | A | A |
| Example 18 | A | A | A |
| Example 19 | A | A | A |
| Example 20 | A | A | A |
| Example 21 | A | A | A |
| Example 22 | A | A | A |
| Example 23 | A | A | A |
| Example 24 | A | A | A |
| Example 25 | A | A | A |
| Example 26 | A | A | A |
| Example 27 | B | B | A |
| Example 28 | C | C | B |
| Example 29 | C | C | B |
| Example 30 | B | B | A |
| Example 31 | A | A | A |
| Example 32 | C | C | A |
| Example 33 | A | A | A |
| Example 34 | B | B | A |
| Example 35 | B | B | A |
| Example 36 | C | C | B |
| Example 37 | A | A | A |
| Example 38 | A | A | A |
| Example 39 | A | A | A |
| Example 40 | A | A | A |
| Example 41 | A | A | A |
| Example 42 | A | A | A |
| Example 43 | A | A | A |
| Example 44 | A | A | A |
| Example 45 | A | A | A |
| Example 46 | C | A | A |
| Example 47 | B | A | A |
| Example 48 | A | A | A |
| Example 49 | A | A | A |
| Example 50 | A | A | A |
| Example 51 | A | A | A |
| Example 52 | A | A | A |
| Example 53 | A | A | A |
| Example 54 | A | A | A |
| Example 55 | A | A | A |
| Example 56 | A | A | A |
| Example 57 | A | A | A |
| Example 58 | A | A | A |
| Example 59 | A | A | B |
| Example 60 | A | A | B |
| Example 61 | A | A | A |
| Example 62 | A | A | A |
| Example 63 | A | A | A |
| Example 64 | A | A | A |
| Example 65 | A | A | A |
| Example 66 | A | A | A |
| Example 67 | A | A | A |
| Example 68 | A | A | A |
| Example 69 | B | A | A |
| Example 70 | B | A | A |
| Example 71 | A | B | B |
| Example 72 | A | B | B |
| Example 73 | A | C | C |
| Example 74 | A | A | A |
| Example 75 | A | A | A |
| Example 76 | A | A | A |
| Example 77 | A | A | A |
| Example 78 | A | A | A |
| Example 79 | A | A | A |
| Example 80 | A | A | A |
| Example 81 | A | A | A |
| Example 82 | A | A | A |
| Example 83 | A | A | A |
| Example 84 | A | A | A |
| Example 85 | A | A | A |
| Example 86 | A | A | A |
| Example 87 | A | A | A |
| Example 88 | A | A | A |
| Example 89 | A | A | A |
| Example 90 | A | A | A |
| Example 91 | A | A | A |
| Example 92 | A | A | A |
| Example 93 | A | C | C |
| Example 94 | A | C | B |
| Comparative | D | D | A |
| Example 1 | | | |

As shown in the above table, in Examples, it was possible to form a film with few defects, good spectral characteristics, and suppressed film thickness reduction.

### Example 1001

A silicon wafer was coated with a green coloring composition by a spin coating method so that a thickness of a film after film formation was 1.0 μm. Next, the silicon wafer was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the green coloring composition was patterned by heating at 200° C. for 5 minutes using a hot plate to form a green pixel. In the same process, a red coloring composition and a blue coloring composition were patterned to sequentially form a red pixel and a blue pixel, thereby forming a color filter having the green pixel, red pixel, and blue pixel. In this color filter, the green pixel was formed in a Bayer pattern, and the red pixel and blue pixel were formed in an island pattern in an adjacent region thereof. The obtained color filter was incorporated into a solid-state imaging element according to a known method. The solid-state imaging element had a suitable image recognition ability. As the green coloring composition, the coloring composition of Example 1 was used. The red coloring composition and blue coloring composition will be described later.

(Red Coloring Composition)

The following components were mixed and stirred, and the obtained mixture was filtered through a nylon filter (manufactured by Nihon Pall Corporation) having a pore size of 0.45 μm to prepare the red coloring composition.

Red pigment dispersion liquid: 51.7 parts by mass

Resin 101: 0.6 parts by mass

Polymerizable compound 101: 0.6 parts by mass

Photopolymerization initiator 101: 0.3 parts by mass

Surfactant 101: 4.2 parts by mass

PGMEA: 42.6 parts by mass

(Blue Coloring Composition)

The following components were mixed and stirred, and the obtained mixture was filtered through a nylon filter (manufactured by Nihon Pall Corporation) having a pore size of 0.45 μm to prepare the blue coloring composition.

Blue pigment dispersion liquid: 44.9 parts by mass

Resin 101: 2.1 parts by mass

Polymerizable compound 101: 1.5 parts by mass

Polymerizable compound 102: 0.7 parts by mass

Photopolymerization initiator 101: 0.8 parts by mass

Surfactant 101: 4.2 parts by mass

PGMEA: 45.8 parts by mass

Raw materials used for the red coloring composition and the blue coloring composition are as follows.

Red Pigment Dispersion Liquid

A mixed solution in which 9.6 parts by mass of C. I. Pigment Red 254, 4.3 parts by mass of C. I. Pigment Yellow 139, 6.8 parts by mass of a dispersant (Disperbyk-161, manufactured by BYK Chemie), and 79.3 parts by mass of PGMEA were blended was mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersion treatment was repeated 10 times, thereby obtaining a Red pigment dispersion liquid.

Blue Pigment Dispersion Liquid

A mixed solution in which 9.7 parts by mass of C. I. Pigment Blue 15:6, 2.4 parts by mass of C. I. Pigment Violet 23, 5.5 parts by mass of a dispersant (Disperbyk-161, manufactured by BYK Chemie), and 82.4 parts by mass of PGMEA were blended was mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersion treatment was repeated 10 times, thereby obtaining a Blue pigment dispersion liquid.

Polymerizable compound 101: KAYARAD DPHA (manufactured by Nippon Kayaku Co., Ltd.)

Polymerizable compound 102: compound having the following structure

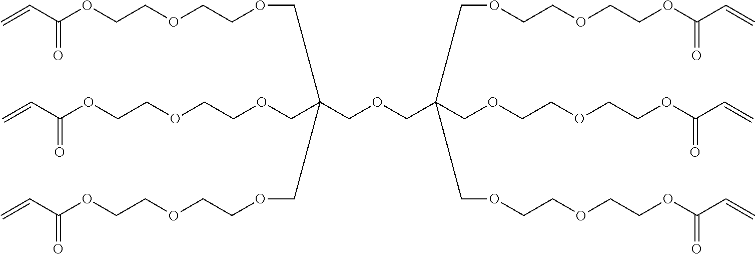 [SMILES: C=CC(=O)OCCOCCOCCCC(CCCOCCOCCOC(=O)C=C)(COCCOCCOC(=O)C=C)COCC(CCCOCCOCCOC(=O)C=C)(CCCOCCOCCOC(=O)C=C)COCCOCCOC(=O)C=C]

Resin 101: resin having the following structure (Mw=11000; the numerical value described together with the main chain indicates a molar ratio)

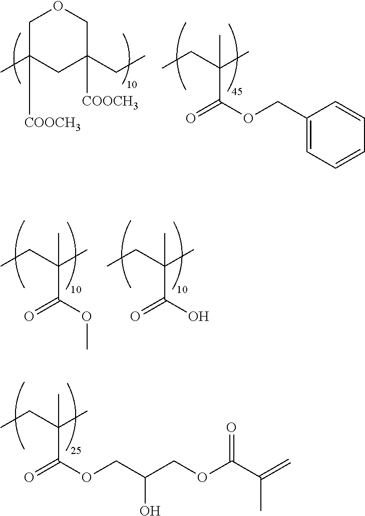

Photopolymerization initiator 101: Irgacure OXE01 (manufactured by BASF)

Surfactant 101: 1% by mass PGMEA solution of a compound having the following structure (Mw=14000; the numerical value “%” representing the proportion of the repeating unit is mol %)

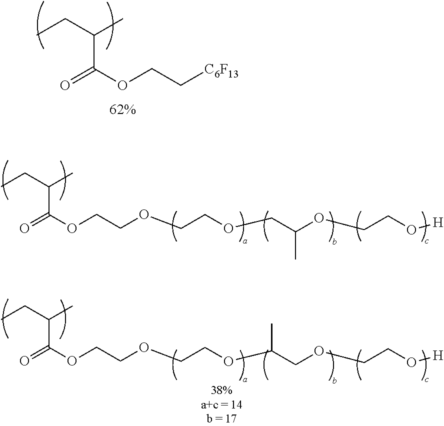

What is claimed is:

1. A coloring composition comprising:
a colorant;
a polymerizable compound; and
a photopolymerization initiator,
wherein the colorant includes a green pigment,
a content of the green pigment in a total solid content of the coloring composition is 25% by mass or more, and
the green pigment includes a compound which is a compound represented by Formula (1) and has a maximal absorption wavelength in a wavelength range of 620 to 730 nm, 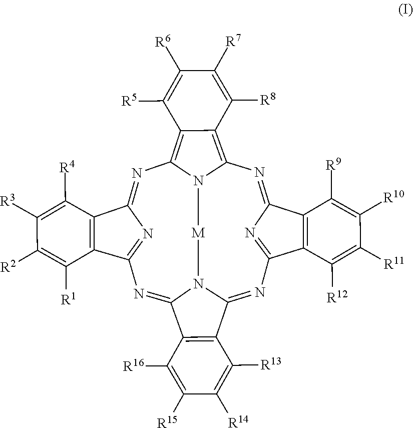
in the formula, R¹ to R¹⁶ each independently represent a hydrogen atom or a substituent,
at least one of R¹, . . . , or R¹⁶ is a group represented by Formula (R-1),
two adjacent groups of R¹ to R¹⁶ may be bonded to each other to form a ring, and
M represents a metal atom, a metal oxide, or a metal halide,
—X¹—R¹⁰⁰ (R-1)
in Formula (R-1), X¹ represents S or NR^{X1},
R^{X1} represents a hydrogen atom or a substituent,
R¹⁰⁰ represents a hydrogen atom or a substituent, and
in a case where X¹ is NR^{X1}, R¹⁰⁰ and R^{X1} may be bonded to each other to form a ring.

2. A coloring composition according to claim 1,
wherein R¹⁰⁰ in Formula (R-1) is a group represented by Formula (R-2),
-A²-R²⁰⁰ (R-2)
in Formula (R-2), A² represents a single bond or a divalent linking group, and
R²⁰⁰ represents a hydrogen atom or a substituent,
where, in a case where R²⁰⁰ is an aryl group, A² is a single bond.

3. The coloring composition according to claim 1,
wherein the content of the green pigment in the total solid content of the coloring composition is 45% by mass or more.

4. The coloring composition according to claim 1,
wherein at least one of R¹, . . . , or R⁴ in Formula (1), at least one of R⁵, . . . , or R⁸ in Formula (1), at least one of R⁹, . . . , or R¹² in Formula (1), and at least one of R¹³, . . . , or R¹⁶ in Formula (1) are each independently the group represented by Formula (R-1).

5. The coloring composition according to claim 1,
wherein X¹ in Formula (R-1) is S.

6. The coloring composition according to claim 1,
wherein M in Formula (1) is Cu, Zn, Fe, VO, or Mg.

7. The coloring composition according to claim 1,
wherein a molecular weight of the compound represented by Formula (1) is 2500 or less.

8. The coloring composition according to claim 1, further comprising:
a yellow pigment.

9. The coloring composition according to claim 1,
wherein the coloring composition is used for forming a pixel of a color filter.

10. The coloring composition according to claim 9,
wherein the coloring composition is used for forming a green pixel.

11. A film obtained from the coloring composition according to claim 1.

12. A color filter comprising:
the film according to claim 11.

13. A solid-state imaging element comprising:
the film according to claim 11.

14. An image display device comprising:
the film according to claim 11.
